(19) United States
(12) Patent Application Publication
(10) Pub. No.: US 2020/0012194 A1
(43) Pub. Date: Jan. 9, 2020

(54) RADIATION-SENSITIVE RESIN COMPOSITION, RESIST PATTERN-FORMING METHOD AND POLYMER COMPOSITION

(71) Applicant: JSR CORPORATION, Minato-ku (JP)

(72) Inventors: Motohiro SHIRATANI, Tokyo (JP); Natsuko Kinoshita, Tokyo (JP); Ken Maruyama, Tokyo (JP)

(73) Assignee: JSR CORPORATION, Minato-ku (JP)

(21) Appl. No.: 16/445,267

(22) Filed: Jun. 19, 2019

(30) Foreign Application Priority Data
Jun. 28, 2018 (JP) 2018-123665
May 28, 2019 (JP) 2019-099793

(51) Int. Cl. G03F 7/039; G03F 7/004; G03F 7/20; C08L 33/14; C08L 25/18

(52) U.S. Cl. CPC G03F 7/0397; G03F 7/0045; C08L 25/18; C08L 33/14; G03F 7/20

(57) ABSTRACT

Provided are a radiation-sensitive resin composition, a resist pattern-forming method and a polymer component. The radiation-sensitive resin composition contains: a polymer component having a first structural unit that includes a phenolic hydroxyl group and a second structural unit that includes an acid-labile group; and a radiation-sensitive acid generator, wherein, the polymer component satisfies inequality (A), wherein, in the inequality (A), X1 represents a proportion (mol %) of the first structural unit comprised with respect to total structural units constituting the polymer component included in a fraction eluted until a retention time at which a cumulative area accounts for 1% of a total area on a gel permeation chromatography (GPC) elution curve of the polymer component detected by a differential refractometer; and X2 represents a proportion (mol %) of the first structural unit comprised with respect to total structural units constituting the polymer component.

X1<X2 (A)

### BACKGROUND OF THE INVENTION

### Field of the Invention

The present invention relates to a radiation-sensitive resin composition, a resist pattern-forming method and a polymer composition.

### DESCRIPTION OF THE RELATED ART

A radiation-sensitive composition for use in microfabrication by lithography generates an acid at a light-exposed region upon an irradiation with a radioactive ray, e.g., an electromagnetic wave such as a far ultraviolet ray such as an ArF excimer laser beam, a KrF excimer laser beam, etc., an extreme ultraviolet ray (EUV), or a charged particle ray such as an electron beam. A chemical reaction in which the acid serves as a catalyst causes the difference in rates of dissolution in a developer solution, between light-exposed regions and light-unexposed regions, whereby a resist pattern is formed on a substrate.

Such a radiation-sensitive resin composition is demanded to be favorable in sensitivity to exposure light such as EUV or an electron beam and also superior in not only resolution but also a LWR (Line Width Roughness) performance, thereby enabling a highly accurate pattern to be obtained. To address the demands, the structure of the polymer contained in the radiation-sensitive resin composition has been extensively studied, and it is known that incorporation of a lactone structure such as a butyrolactone structure and a norbornanelactone structure can improve these performances (see Japanese Unexamined Patent Application, Publication Nos. H11-212265, 2003-5375 and 2008-83370).

### PRIOR ART DOCUMENTS

### Patent Documents

Patent Document 1: Japanese Unexamined Patent Application, Publication No. H11-212265

Patent Document 2: Japanese Unexamined Patent Application, Publication No. 2003-5375

Patent Document 3: Japanese Unexamined Patent Application, Publication No. 2008-83370

### SUMMARY OF THE INVENTION

### Problems to be Solved by the Invention

However, under current circumstances in which miniaturization of resist patterns has proceeded to a level for line widths of no greater than 40 nm, required levels for the aforementioned performances are further elevated, and the conventional radiation-sensitive resin composition described above is not capable of meeting these demands. Moreover, miniaturization of resist patterns is recently accompanied by in particular, demands for inhibition of generation of defects in the resist patterns.

The present invention was made in view of the foregoing circumstances, and an object of the invention is to provide a radiation-sensitive resin composition, a resist pattern-forming method and a polymer composition being superior in inhibitory ability of defects and in LWR performances while the sensitivity is maintained.

### Means for Solving the Problems

According to one aspect of the invention made for solving the aforementioned problems, a radiation-sensitive resin composition contains:

a polymer component (hereinafter, may be also referred to as “(A) polymer component” or “polymer component (A)”) having in a single polymer or different polymers, a first structural unit that includes a phenolic hydroxyl group (hereinafter, “structural unit (I)”hereinafter, may be also referred to as), and a second structural unit that includes an acid-labile group (hereinafter, may be also referred to as “structural unit (II)”);

and a radiation-sensitive acid generator (hereinafter, may be also referred to as “(B) acid generator” or “acid generator (B)”)

wherein, the polymer component (A) satisfies the following inequality (A):

X1<X2 (A)

wherein, in the inequality (A), X1 represents a proportion (mol %) of the first structural unit included with respect to total structural units constituting the polymer component included in a fraction eluted until a retention time at which a cumulative area accounts for 1% of a total area on a gel permeation chromatography (GPC) elution curve of the polymer component detected by a differential refractometer; and X2 represents a proportion (mol %) of the first structural unit included with respect to total structural units constituting the polymer component.

According to other aspect of the invention made for solving the aforementioned problems, a radiation-sensitive resin composition contains:

a polymer component (polymer component (A)) having in a single polymer or different polymers, a first structural unit that includes a phenolic hydroxyl group (structural unit (I)) and a second structural unit that includes an acid-labile group (structural unit (II)); and

a radiation-sensitive acid generator (acid generator (B)),

wherein the polymer component (A)satisfies the following inequality (B):

$$\frac{X 2}{X 1} > 1.0 \qquad ( B )$$

wherein, in the inequality (B), X1 represents a proportion (mol %) of the first structural unit included with respect to total structural units constituting the polymer component included in a fraction eluted until a retention time at which a cumulative area accounts for 1% of a total area on a gel permeation chromatography (GPC) elution curve of the polymer component detected by a differential refractometer; and X2 represents a proportion (mol %) of the first structural unit comprised with respect to total structural units constituting the polymer component.

According to still other aspect of the invention made for solving the aforementioned problems, a resist pattern-forming method includes: applying the radiation-sensitive resin composition of the above aspect directly or indirectly on a substrate; exposing a resist film provided by the applying; and developing the resist film exposed.

According to yet other aspect of the invention made for solving the aforementioned problems, a polymer composition contains a polymer component having in a single polymer or different polymers, a first structural unit that includes a phenolic hydroxyl group and a second structural unit that includes an acid-labile group,

wherein, the polymer component satisfies the following inequality (A):

X1<X2 (A)

wherein, in the inequality (A), X1 represents a proportion (mol %) of the first structural unit included with respect to total structural units constituting the polymer component included in a fraction eluted until a retention time at which a cumulative area accounts for 1% of a total area on a gel permeation chromatography (GPC) elution curve of the polymer component detected by a differential refractometer; and X2 represents a proportion (mol %) of the first structural unit included with respect to total structural units constituting the polymer component.

According to a further aspect of the invention made for solving the aforementioned problems, a polymer composition contains a polymer component having in a single polymer or different polymers, a first structural unit that includes a phenolic hydroxyl group and a second structural unit that includes an acid-labile group,

the polymer component satisfies inequality (B):

$$\frac{X 2}{X 1} > 1.0 \qquad ( B )$$

wherein, in the inequality (B), X1 represents a proportion (mol %) of the first structural unit included with respect to total structural units constituting the polymer component included in a fraction eluted until a retention time at which a cumulative area accounts for 1% of a total area on a gel permeation chromatography (GPC) elution curve of the polymer component detected by a differential refractometer; and X2 represents a proportion (mol %) of the first structural unit included with respect to total structural units o constituting the polymer component.

### Effects of the Invention

The radiation-sensitive resin composition and the resist pattern-forming method of the aspects of the present invention enable a resist pattern with less LWR and fewer defects to be formed while the sensitivity is maintained. The polymer composition of the aspect of the present invention can be suitably used as a component of the radiation-sensitive resin composition of the above aspect of the invention. Therefore, these can be suitably used in manufacture of semiconductor devices in which further progress of miniaturization is expected in the future.

### BRIEF DESCRIPTION OF THE DRAWINGS

FIG. 1 is a view illustrating a fraction (fraction A) eluted until a retention time at which a cumulative area accounts for 1% of a total area on a gel permeation chromatography (GPC) elution curve in calculating X1.

### DESCRIPTION OF THE EMBODIMENTS

### Radiation-Sensitive Resin Composition

The radiation-sensitive resin composition of one embodiment of the present invention contains the polymer component (A) and the acid generator (B). The radiation-sensitive resin composition typically contains a solvent (hereinafter, may be also referred to as “(D) solvent” or “solvent (D)”). In addition, the radiation-sensitive resin composition may also contain as a favorable component, an acid diffusion controller (hereinafter, may be also referred to as “(C) acid diffusion controller” or “acid diffusion controller (C)”), and may further contain other optional component(s) within a range not leading to impairment of the effects of the present invention.

The radiation-sensitive resin composition is superior in inhibitory ability of defects and in LWR performances while the sensitivity is maintained. Although not necessarily clarified and without wishing to be bound by any theory, the reason for achieving the effects described above due to the radiation-sensitive resin composition having the aforementioned constitution is inferred as in the following, for example. The present inventors have found that a component having a high molecular weight having a great proportion of the structural unit (I) contained may cause defects. As a result of thorough investigations in view of such findings, the present inventors found that the aforementioned effects are achieved when the polymer component (A) having in a single polymer or different polymers, the structural unit (I) that includes a phenolic hydroxyl group, and the structural unit (II) that includes an acid-labile group is used, in which the proportion (X1) of the structural unit (I) falling under a high-molecular weight region is less than the proportion (X2) of the structural unit (I) included with respect to total structural units constituting the polymer component (A). It is believed that use of such a polymer component (A) improves an inhibitory ability of defects and an LWR performance of the radiation-sensitive resin composition.

Hereinafter, each component will be described.

### (A) Polymer Component

The polymer component (A) has in a single polymer or different polymers, the structural unit (I) and the structural unit (II). As referred to herein, the “polymer component” may include not only one type of polymer, but a mixture of a plurality of types of polymers. In other words, the polymer component (A) may be either one type of polymer having the structural unit (I) and the structural unit (II), or a mixture of a polymer having at least the structural unit (I) and a polymer having at least the structural unit (II). It is to be noted that the polymer component (A) may also include a polymer having neither the so structural unit (I) nor the structural unit (II).

The polymer component (A) may be contained in the radiation-sensitive resin composition in, for example: (i) a form of including one type of a polymer having the structural unit (I) and the structural unit (II); (ii) a form of a mixture of a plurality of types of polymers having the structural unit (I) and the structural unit (II); (iii) a form of a mixture of a polymer having the structural unit (I) and a polymer having the structural unit (II); (iv) a form of both the options (i) and (iii); (v) a form of both the options (ii) and (iii); or the like. Of these, the option (i) or (ii) is preferred in light of more improvements of the inhibitory ability of defects, and the LWR performance.

The polymer component (A) satisfies the inequality (A) as described later. Also, the polymer component (A) satisfies the inequality (B) as described later. The polymer component (A) may also have other structural unit than the structural unit (I) or the structural unit (II). The polymer component (A) may have each structural unit of each a single type, or two or more types. Hereinafter, each structural unit will be described.

Structural Unit (I)

The structural unit (I) includes a phenolic hydroxyl group. The term “phenolic hydroxyl group” as referred to herein means a hydroxy group directly bonding to an aromatic ring, in general, not being limited to a hydroxy group directly bonding to a benzene ring. Due to having the structural unit (I), the polymer component (A) is capable of enhancing the hydrophilicity of a resist film, enables the solubility in a developer solution to be appropriately adjusted, and also enables the adhesiveness of a resist pattern to the substrate to be improved. Additionally, in the case of an exposure with KrF, EUV or an electron beam, the sensitivity of the radiation-sensitive resin composition can be more improved.

Examples of the structural unit (I) include a structural unit represented by the following formula (1), and the like.

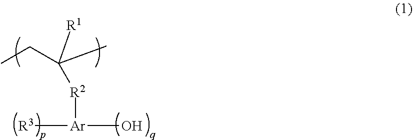

In the above formula (1), R¹ represents a hydrogen atom, a fluorine atom, a methyl group or a trifluoromethyl group; R² represents a single bond, —O—, —COO—* or —CONH—*, wherein * denotes a binding site to Ar; Ar represents a group obtained from an arene having 6 to 20 ring atoms by removing (p+q+1) hydrogen atoms on the aromatic ring; p is an integer of 0 to 10, in a case in which p is 1, R³ represents a monovalent organic group having 1 to 20 carbon atoms or a halogen atom, wherein in a case in which p is no less than 2, a plurality of R³s are identical or different and each represent a monovalent organic group having 1 to 20 carbon atoms or a halogen atom, or at least two of the plurality of R³s taken together represent a part of a ring structure having 4 to 20 ring atoms together with the carbon atom to which the at least two of the plurality of R³ bond; and q is an integer of 1 to 11, wherein (p+q) is no greater than 11.

R¹ represents, in light of the degree of copolymerization of a monomer that gives a structural unit (I), preferably a hydrogen atom or a methyl group, and more preferably a hydrogen atom.

R² represents preferably a single bond or —COO—*, and more preferably a single bond.

The term number of “ring atoms” as referred to herein means the number of atoms so constituting the ring in an alicyclic structure, an aromatic carbocyclic structure, an aliphatic heterocyclic structure or an aromatic heterocyclic structure, and in the case of a polycyclic ring structure, the number of “ring atoms” means the number of atoms constituting the polycyclic ring.

Examples of the arene having 6 to 20 ring atoms that gives Ar include benzene, naphthalene, anthracene, phenanthrene, tetracene, pyrene and the like. Of these, benzene or naphthalene is preferred, and benzene is more preferred.

The term “organic group” as referred to herein means a group that includes at least one carbon atom. The monovalent organic group having 1 to 20 carbon atoms represented by R³ is exemplified by: a monovalent hydrocarbon group having 1 to 20 carbon atoms; a group that includes a divalent hetero atom-containing group between two adjacent carbon atoms or at the end of the atomic bonding side of the monovalent hydrocarbon group having 1 to 20 carbon atoms; a group obtained by substituting a part or all of hydrogen atoms of the monovalent hetero atom-containing group included in the monovalent hydrocarbon group having 1 to 20 carbon atoms or the group that includes the divalent hetero atom-containing group; and the like.

The “hydrocarbon group” may include a chain hydrocarbon group, an alicyclic hydrocarbon group and an aromatic hydrocarbon group. This “hydrocarbon group” may be a saturated hydrocarbon group or an unsaturated hydrocarbon group. The “chain hydrocarbon group” as referred to herein means a hydrocarbon group not including a ring structure but comprising only a chain structure, and both a straight chain hydrocarbon group and a branched hydrocarbon group may be involved. The “alicyclic hydrocarbon group” as referred to herein means a hydrocarbon group not including an aromatic structure but comprising only an alicyclic structure as the ring structure, and both a monocyclic alicyclic hydrocarbon group and a polycyclic alicyclic hydrocarbon group may be involved. However, the alicyclic hydrocarbon group does not need to be constituted with only the alicyclic structure, and a part thereof may include a chain structure. The “aromatic hydrocarbon group” as referred to herein means a hydrocarbon group including an cyclic structure as the ring structure. However, the aromatic hydrocarbon group does not need to be constituted with only the cyclic structure, and a part thereof may include a chain structure and/or an alicyclic structure.

The monovalent hydrocarbon group having 1 to 20 carbon atoms is exemplified by a monovalent chain hydrocarbon group having 1 to 20 carbon atoms, monovalent alicyclic hydrocarbon group having 3 to 20 carbon atoms, monovalent aromatic hydrocarbon group having 6 to 20 carbon atoms and the like.

Examples of the monovalent chain hydrocarbon group having 1 to 20 carbon atoms include:

alkyl groups such as a methyl group, an ethyl group, a n-propyl group and an i-propyl group;

alkenyl groups such as an ethenyl group, a propenyl group and a butenyl group;

alkynyl groups such as an ethynyl group, a propynyl group and a butynyl group; and the like.

Examples of the monovalent alicyclic hydrocarbon group having 3 to 20 carbon atoms include:

alicyclic saturated hydrocarbon groups such as a cyclopentyl group, a cyclohexyl group, a norbornyl group, an adamantyl group, a tricyclodecyl group and a tetracyclododecyl group;

alicyclic unsaturated hydrocarbon groups such as a cyclopentenyl group, a cyclohexenyl group, a norbornenyl group, a tricyclodecenyl group and a tetracyclododecenyl group; and the like.

Examples of the monovalent aromatic hydrocarbon group having 6 to 20 carbon atoms include:

aryl groups such as a phenyl group, a tolyl group, a xylyl group, a naphthyl group and an anthryl group;

aralkyl groups such as a benzyl group, a phenethyl group, a naphthylm ethyl group, and an anthryl methyl group; and the like.

Examples of the hetero atom constituting the monovalent or divalent hetero atom-containing group include an oxygen atom, a nitrogen atom, a sulfur atom, a phosphorus atom, a silicon atom, a halogen atom, and the like. Examples of the halogen atom include a fluorine atom, a chlorine atom, a bromine atom, and an iodine atom.

Examples of the divalent hetero atom-containing group include —O—, —CO—, —S—, —CS—, —NR′—, a group obtained by combining two or more of these, and the like, wherein R′ represents a hydrogen atom or a monovalent hydrocarbon group.

Examples of the monovalent hetero atom-containing group include halogen atoms such as a fluorine atom, a chlorine atom, a bromine atom and an iodine atom, a hydroxy group, a carboxy group, a cyano group, an amino group, a sulfanyl group, and the like.

R³ represents preferably a monovalent hydrocarbon group, and more preferably an alkyl group.

Examples of the ring structure having 4 to 20 ring atoms represented taken together by two or more of the plurality of R³s include: alicyclic structures such as a cyclopentane structure, a cyclohexane structure, a cyclopentene structure and a cyclohexene structure; aliphatic heterocyclic structures such as a lactone structure and a cyclic ether structure; and the like.

In the above formula (1), p is preferably 0 to 2, more preferably 0 or 1, and still more preferably 0.

In the above formula (1), q is preferably 1 to 3, and more preferably 1 or 2.

Examples of the structural unit (I) include structural units represented by the following formulae (1-1) to (1-12) (hereinafter, may be also referred to as “structural units (I-1) to (I-12)”), and the like.

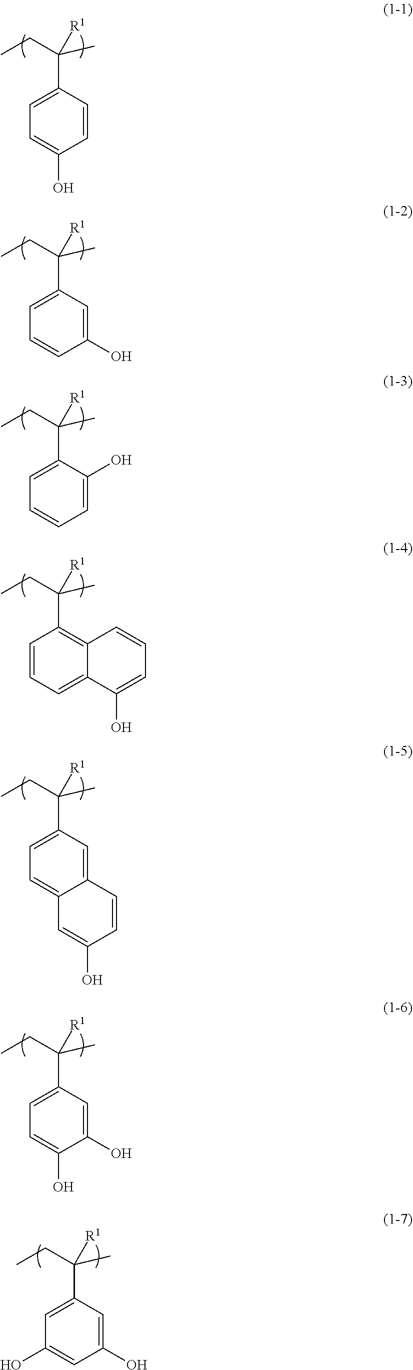

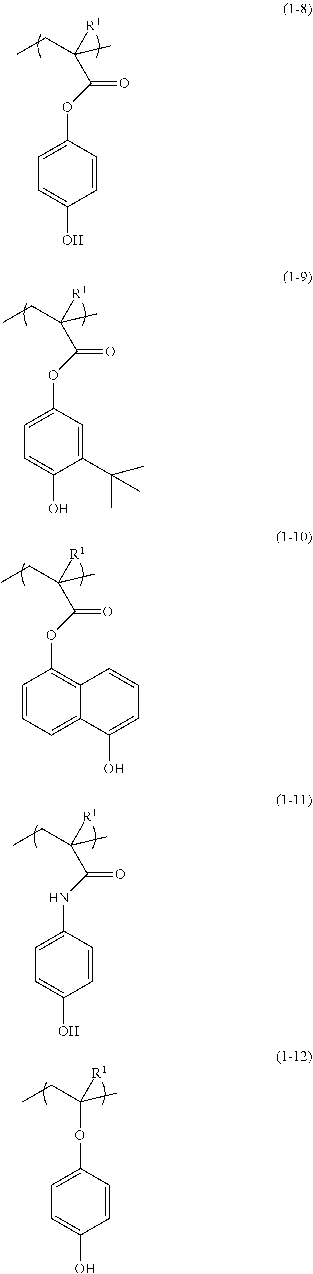

In the above formulae (1-1) to (1-12), R¹ is as defined in the above formula (1).

Of these, the structural unit (I-1), (I-2), (I-6) or (I-8) is preferred.

The lower limit of the proportion of the structural unit (I) contained with respect to the total structural units constituting the polymer component (A) is preferably 10 mol %, more preferably 20 mol %, and still more preferably 30 mol %. The upper limit of the proportion of the structural unit (I) contained is preferably 80 mol %, more preferably 70 mol %, and still so more preferably 60 mol %. When the proportion of the structural unit (I) contained falls within the above range, more improvements of the inhibitory ability of defects, and the LWR performance of the radiation-sensitive resin composition are enabled.

Structural Unit (II)

The structural unit (II) includes an acid-labile group (hereinafter, may be also referred to as “acid-labile group (a)”). The term “acid-labile group” as referred to herein means a group that substitutes for the hydrogen atom included in a carboxy group, a sulfo group, a phenolic hydroxyl group and the like, and that will be dissociated by an action of an acid. The acid-labile group (a) is dissociated by an action of an acid from the acid generator (B) generated upon an exposure, leading to a change in a solubility of the polymer component (A) in a developer solution, thereby enabling a resist pattern to be formed.

The structural unit (II) is exemplified by a structural unit represented by the following formula (2-1A), formula (2-1B), formula (2-1C), formula (2-2A) or formula (2-2B), and the like. —CR^{X}R^{Y}R^{Z}, a group that includes an unsaturated alicyclic structure or —CR^{U}R^{V}(OR^{W}), which bonds to an oxy-oxygen atom derived from a carboxy group or a phenolic hydroxyl group may be the acid-labile group (a).

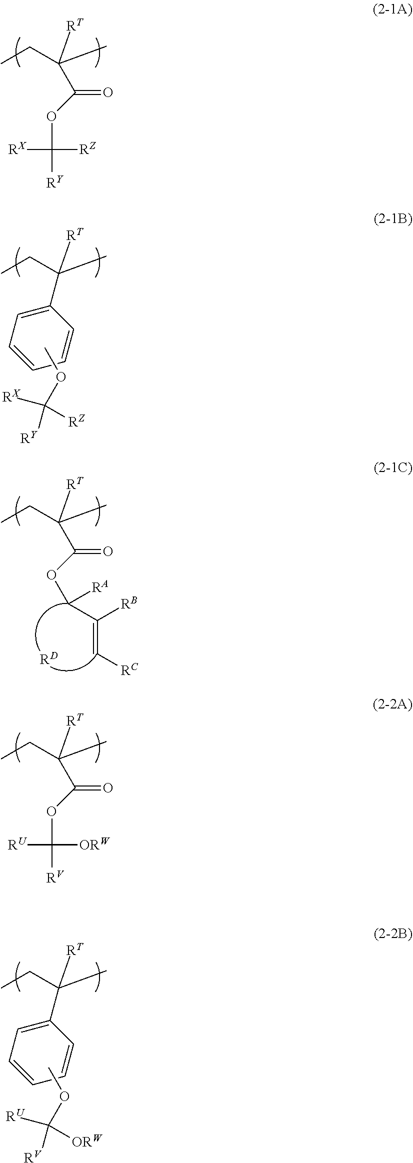

In the above formulae (2-1A), (2-1B), (2-1C), (2-2A) and (2-2B), R^{T}s each independently represent a hydrogen atom, a fluorine atom, a methyl group or a trifluoromethyl group.

In the above formulae (2-1A) and (2-1B), R^{X}s each independently represent a monovalent hydrocarbon group having 1 to 20 carbon atoms; and R^{Y} and R^{Z} each independently represent a monovalent hydrocarbon group having 1 to 20 carbon atoms, or R^{Y} so and R^{Z} taken together represent a part of an alicyclic structure having 3 to 20 ring atoms together with the carbon atom to which R^{Y} and R^{Z} bond.

In the formula (2-1C), R^{A} represents a hydrogen atom; R^{B} and R^{C} each independently represent a hydrogen atom or a monovalent hydrocarbon group having 1 to 20 carbon atoms; and R^{D} represents a divalent hydrocarbon group having 1 to 20 carbon atoms that constitutes an unsaturated alicyclic structure having 4 to 20 ring atoms together with the carbon atoms to which R^{A}, R^{B} and R^{C} bond, respectively.

In the above formulae (2-2A) and (2-2B), R^{U} and R^{V} each independently represent a hydrogen atom or a monovalent hydrocarbon group having 1 to 20 carbon atoms; and R^{W} represents a monovalent hydrocarbon group having 1 to 20 carbon atoms, or R^{U} and R^{V} taken together represent a part of an alicyclic structure having 3 to 20 ring atoms together with the so carbon atom to which R^{U} and R^{V} bond, or R^{U} and R^{W} taken together represent a part of an aliphatic heterocyclic structure having 5 to 20 ring atoms together with the carbon atom to which R^{U} bonds and with the oxygen atom to which R^{W} bonds.

R^{T} represents preferably a hydrogen atom or a methyl group in light of the degree of copolymerization of a monomer that gives a structural unit (II)

Examples of the monovalent hydrocarbon group having 1 to 20 carbon atoms which may be represented by R^{X}, R^{Y}, R^{Z}, R^{B}, R^{C}, R^{U}, R^{V} or R^{W} include groups similar to the hydrocarbon groups exemplified as R³ in the above formula (1), and the like.

Examples of the divalent hydrocarbon group having 1 to 20 carbon atoms represented by R^{D} include groups obtained by removing one hydrogen atom from the monovalent hydrocarbon group exemplified as R³ in the above formula (1), and the like.

R^{X} represents preferably an alkyl group or an aryl group.

R^{Y} and R^{Z} each represent preferably an alkyl group or an alicyclic saturated hydrocarbon group.

Examples of the alicyclic structure having 3 to 20 ring atoms represented taken together by R^{Y} and R^{Z} or R^{U} and R^{V} include:

saturated alicyclic structures such as a cyclopropane structure, a cyclobutane structure, a cyclopentane structure, a cyclohexane structure, a norbornane structure and an adamantane structure;

unsaturated alicyclic structures such as a cyclopropene structure, a cyclobutene structure, a cyclopentene structure, a cyclohexene structure and a norbornene structure; and the like.

Of these, a cyclopentane structure, a cyclohexane structure, a cyclohexene structure or an adamantane structure is preferred.

Examples of the unsaturated alicyclic structure having 4 to 20 ring atoms represented by R^{D} together with the carbon atoms to which R^{A}, R^{B} and R^{C} bond, respectively, include unsaturated alicyclic structures such as a cyclobutene structure, a cyclopentene structure, a cyclohexene structure and a norbornene structure, and the like.

Examples of the aliphatic heterocyclic structure having 5 to 20 ring atoms represented by R^{U} and R^{W} taken together include: saturated oxygen-containing heterocyclic structures such as an oxacyclobutane structure, an oxacyclopentane structure and an oxacyclohexane structure; unsaturated oxygen-containing heterocyclic structures such as an oxacyclobutene structure, an oxacyclopentene structure and an oxacyclohexene structure; and the like.

The structural unit represented by the above formula (2-1A) is preferably a structural unit derived from 1-alkylcycloalkan-1-yl (meth)acrylate, a structural unit derived from 1-arylcycloalkan-1-yl (meth)acrylate, or a structural unit derived from 2-adamantylpropan-2-yl (meth)acrylate. The structural unit represented by the above formula (2-1B) is preferably a structural unit derived from t-alkyloxystyrene. The structural unit represented by the above formula (2-1C) is preferably a structural unit derived from cyclohexen-3-yl (meth)acrylate. The structural unit represented by the above formula (2-2A) is preferably (1-ethoxy)ethoxy (meth)acrylate. The structural unit represented by the above formula (2-2B) is preferably p-(1-ethoxy)ethoxystyrene.

The structural unit (II) is preferably the structural unit represented by the above formula (2-1A), (2-1B) or (2-1C).

The lower limit of the proportion of the structural unit (II) contained with respect to the total structural units constituting the polymer component (A) is preferably 5 mol %, more preferably 10 mol %, still more preferably 15 mol %, and particularly preferably 20 mol %. The upper limit of the proportion of the structural unit (II) contained is preferably 90 mol %, more preferably 80 mol %, still more preferably 70 mol %, and particularly preferably 65 mol %. When the proportion of the structural unit (II) contained falls within the above range, the sensitivity of the radiation-sensitive composition can be more enhanced, thereby consequently enabling the inhibitory ability of defects, and the LWR performance to be more improved.

Other Structural Unit

The polymer component (A) may have in a single polymer or different polymers, other structural unit than the structural unit (I) or the structural unit (II). The other structural unit is exemplified by: a structural unit (hereinafter, may be also referred to as “structural unit (III)”) that includes a lactone structure, a cyclic carbonate structure, a sultone structure or a combination thereof; a structural unit (hereinafter, may be also referred to as “structural unit (IV)”) that includes an alcoholic hydroxy group other than the structural unit (III); a structural unit (hereinafter, may be also referred to as “structural unit (V)”) that includes an acid-nonlabile hydrocarbon group; and the like.

It is preferred that the polymer component (A) has the other structural unit. The radiation-sensitive resin composition in which the polymer component (A) has the other structural unit tends to lead to the inhibitory ability of defects, and the LWR performance being more improved. Hereinafter, the structural units (III) to (V) will be described.

Structural unit (III)

The structural unit (III) includes a lactone structure, a cyclic carbonate structure, a sultone structure or a combination thereof. When the polymer component (A) has the o structural unit (III), solubility in a developer solution can be improved and consequently, the inhibitory ability of defects, and the LWR performance of the radiation-sensitive composition can be more improved. In addition, the adhesiveness of the resist pattern with the substrate can be more improved.

Examples of the structural unit (III) include structural units represented by the following formulae, and the like.

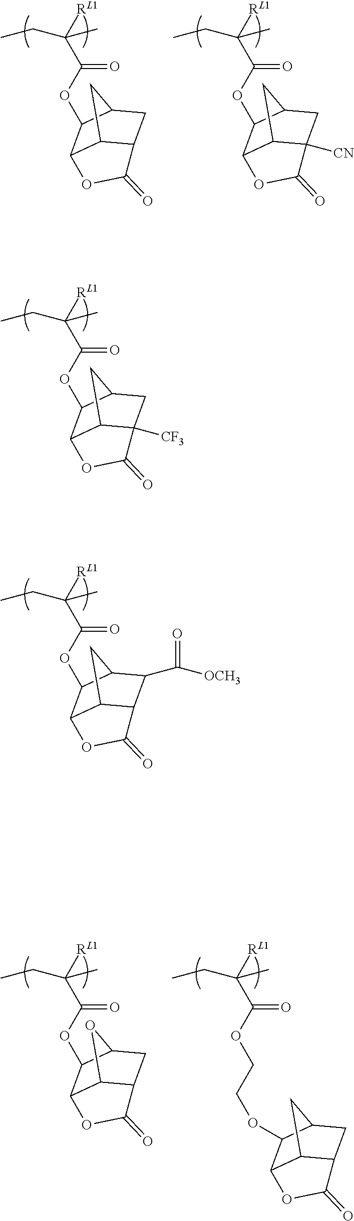

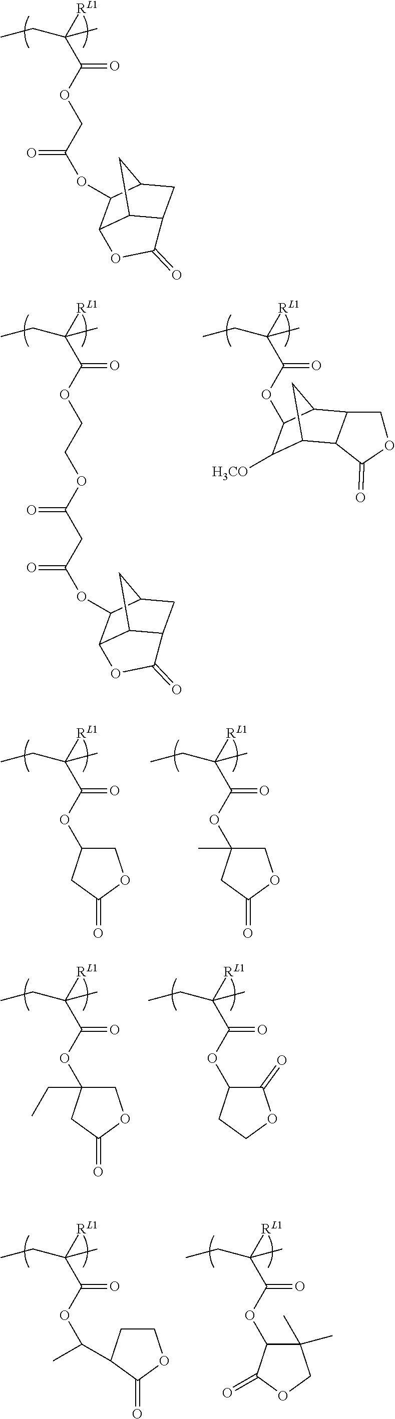

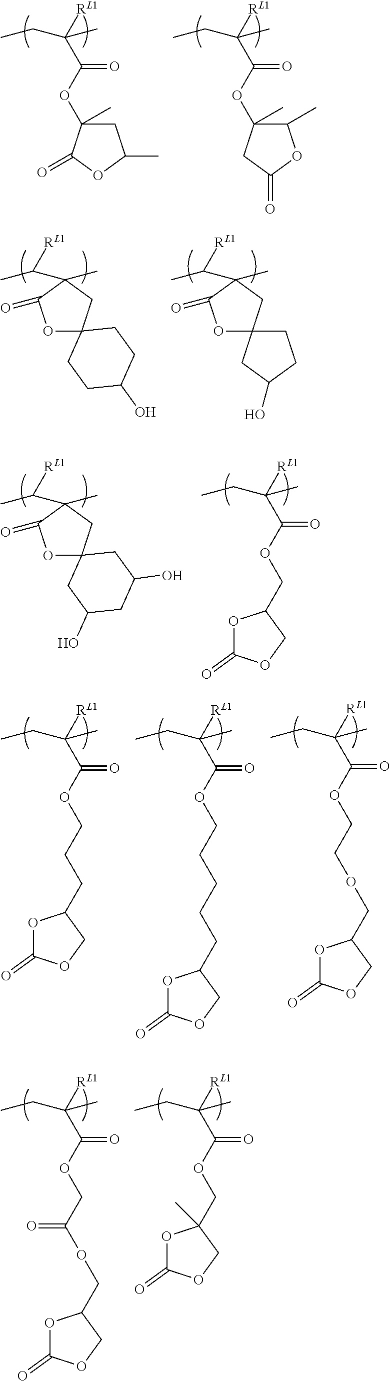

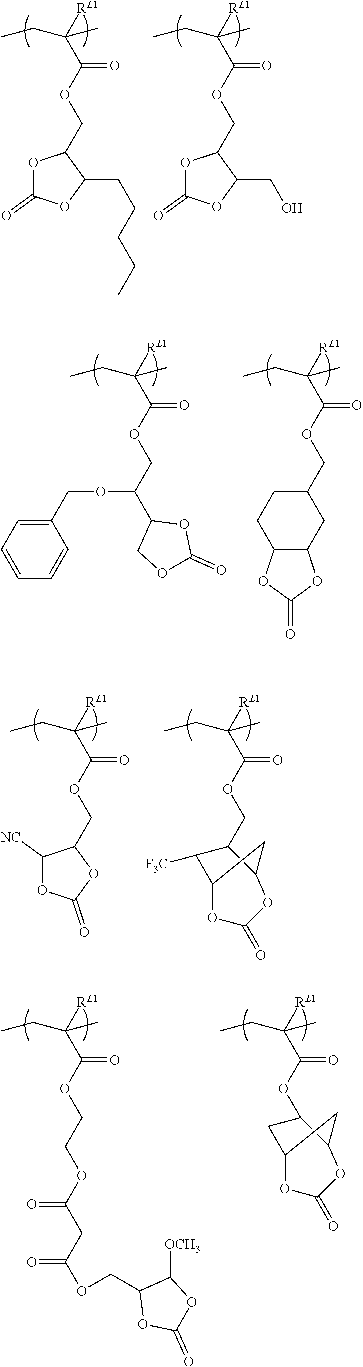

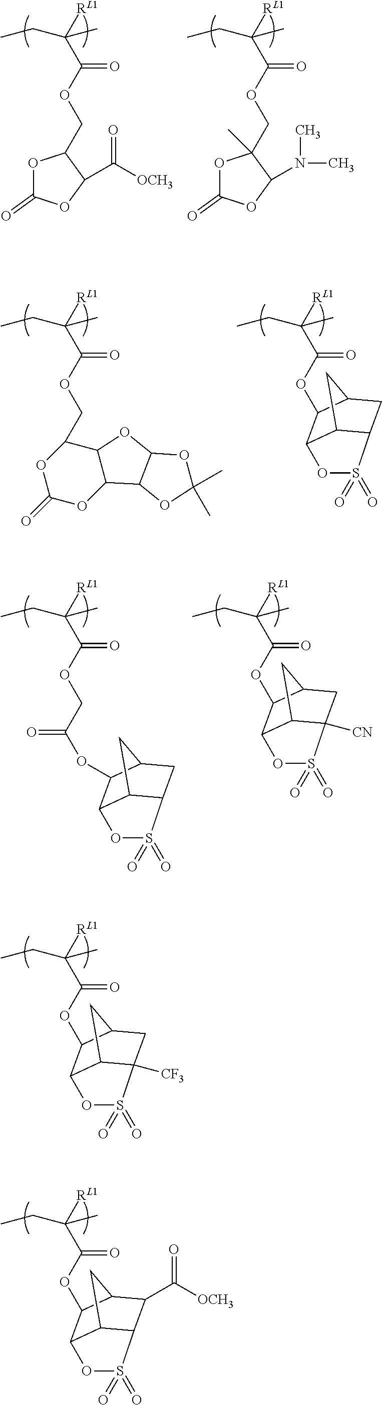

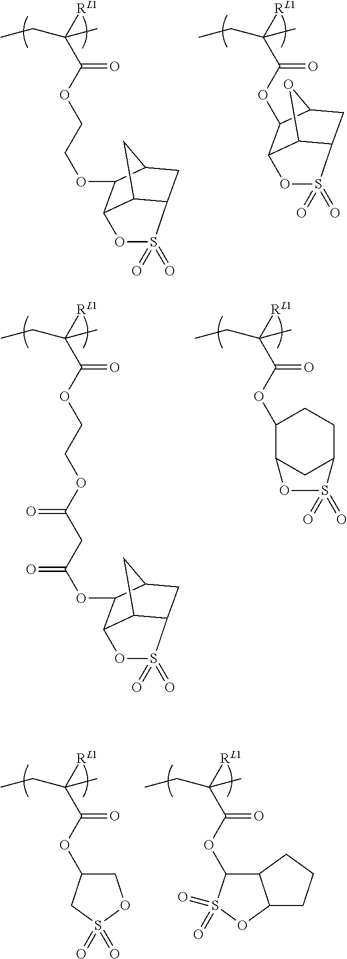

In the above formulae, R^{L1} represents a hydrogen atom, a fluorine atom, a methyl group or a trifluoromethyl group.

The structural unit (III) is preferably a structural unit that includes a lactone structure, more preferably a structural unit that includes a norbornanelactone structure, and still more preferably a structural unit derived from cyanonorbornanelactone-yl (meth)acrylate.

In a case in which the polymer component (A) has the structural unit (III), the upper limit of the proportion of the structural unit (III) contained with respect to total structural units constituting the polymer component is preferably 60 mol %, more preferably 50 mol %, and still more preferably 30 mol %. The lower limit of the proportion of the structural unit (III) is, for example, 1 mol %.

Structural Unit (IV)

The structural unit (IV) includes an alcoholic hydroxy group other than the structural unit (III). When the polymer component (A) has the structural unit (IV), solubility in a developer solution can be improved and consequently, the inhibitory ability of defects, and the LWR performance of the radiation-sensitive composition can be more improved.

Examples of the structural unit (IV) include: structural units that include a hydroxychain hydrocarbon group or a hydroxyalicyclic hydrocarbon group such as a structural unit derived from 3-hydroxyadamantan-1-yl (meth)acrylate; a structural unit derived from 2-hydroxyethyl (meth)acrylate; structural units that include a hydroxyfluorinated alkyl group such as a structural unit derived from 2-hydroxy-2-trifluoromethyl-1,1,1-trifluoropropan-1-ylnorbornane-yl (meth)acrylate; and the like.

In a case in which the polymer component (A) has the structural unit (IV), the upper limit of the proportion of the structural unit (IV) contained with respect to total structural units constituting the polymer component is preferably 60 mol %, and more preferably 50 mol %. The lower limit of the proportion of the structural unit (IV) is, for example, 1 mol %.

Structural Unit (V)

The structural unit (V) includes an acid-nonlabile hydrocarbon group. When the polymer component (A) has the structural unit (V), solubility in a developer solution can be improved and consequently, the inhibitory ability of defects, and the LWR performance of the radiation-sensitive composition can be more improved.

Examples of a monomer that gives a structural unit (V) include styrene, vinylnaphthalene, phenyl (meth)acrylate, benzyl (meth)acrylate, n-pentyl (meth)acrylate, cyclohexyl (meth)acrylate, spiro[tetrahydronaphthalene-1,5′-methylenebutyrolactone], and the like.

In a case in which the polymer component (A) has the structural unit (V), the upper limit of the proportion of the structural unit (V) contained with respect to the total structural units constituting the polymer component (A) is preferably 60 mol %, and more preferably 50 mol %. The lower limit of the proportion of the structural unit (V) is, for example, 1 mol %.

The lower limit of polystyrene equivalent weight-average molecular weight (Mw) of the polymer component (A) as determined by gel permeation chromatography (GPC) is preferably 2,000, more preferably 3,000, still more preferably 4,000, and particularly preferably 5,000. The upper limit of the Mw is preferably 50,000, more preferably 30,000, still more preferably 15,000, and particularly preferably 8,000. When the Mw of the polymer component (A) falls within the above range, coating characteristics of the radiation-sensitive resin composition can be more improved.

The lower limit of the dispersity index, i.e., a ratio of the polystyrene-equivalent number-average molecular weight (Mn) to Mw (Mw/Mn) as determined by GPC, of the polymer component (A) is preferably 1.1, more preferably 1.25, still more preferably 1.4, and particularly preferably 1.5. The upper limit of the dispersity index is preferably 5, more preferably 3, and still more preferably 2. When the Mw/Mn of the polymer component (A) falls within the above range, more improvements of the inhibitory ability of defects, and the LWR performance of the radiation-sensitive resin composition are enabled.

Mw and Mn of the polymer component referred to herein are determined by using gel permeation chromatography (GPC) under the following conditions.

GPC columns: “G2000 HXL” x 2, “G3000 HXL” x 1, and “G4000 HXL” x 1, available from Tosoh Corporation;

flow rate: 1.0 mL/min;

elution solvent: tetrahydrofuran;

sample concentration: 1.0% by mass;

amount of injected sample: 100 μL;

column temperature: 40° C.;

detector: differential refractometer; and

standard substance: mono-dispersed polystyrene

Inequality (A)

The polymer component (A) satisfies the following inequality (A).

X1<X2 (A)

In the above inequality (A), X1 represents a proportion (mol %) of the structural unit (I) included with respect to total structural units constituting the polymer component (A) included in a fraction (hereinafter, may be also referred to as “fraction A”) eluted until a retention time at which a cumulative area accounts for 1% of a total area on a gel permeation chromatography (GPC) elution curve of the polymer component (A) detected by a differential refractometer; and X2 represents a proportion (mol %) of the structural unit (I) included with respect to total structural units constituting the polymer component (A).

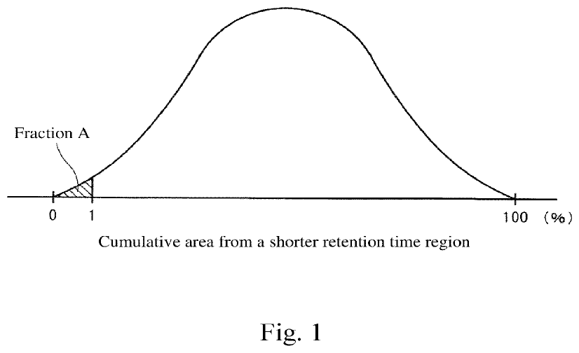

X1 (mol %) may be determined by, for example, preparatively collecting the fraction A that corresponds to an area accounting for 1% from a shorter retention time in preparative GPC performed under the following conditions (see, FIG. 1), and then measuring the proportion of the polymer component contained in the fraction A thus collected preparatively, with respect to the total structural units constituting the structural unit (I). It is to be noted that in the preparative GPC, since higher-molecular weight components are preparatively collected more earlily, a fraction of shorter retention time relatively includes higher-molecular weight components in a larger amount as compared with a fraction of a so longer retention time. In a case in which the polymer component (A) is contained in a composition, X1 may be determined by preparatively collecting the polymer component (A) from the composition, and then subjecting the resultant polymer component (A) to preparative GPC in a similar manner to that described above.

preparative GPC columns: “JAIGEL 2.5H+2H” available from Japan Analytical Industry Co., Ltd.;

flow rate: 4.0 mL/min;

elution solvent: tetrahydrofuran;

sample concentration: 3% by mass;

amount of injected sample: 3 mL;

column temperature: 40° C.; and

detector: differential refractometer

The proportion of the structural unit (I) contained in the polymer component may be determined by using, for example, PyGC-MS (Agilent Technologies, Inc., etc.) to calculate an area ratio of each monomer that gives each structural unit, and then summing up the area ratios for the monomer that gives a structural unit (I), among the area ratios of respective monomers.

X2 (mol %) may be determined by using, for example, PyGC-MS to measure the proportion of the structural unit (I) contained with respect to the total structural units constituting the polymer component, on the entirety of the polymer component (A) with out performing the preparative collection. The proportion of the structural unit (I) contained may be determined in a similar manner to that described above.

Accordingly, with respect to the proportion (mol %) of the structural unit (I) in the polymer component (A), the proportion (X1) with respect to the total area, falling under a high-molecular weight region of the accumulative area accounting for 1% from the higher-molecular weight side on a gel permeation chromatography elution curve detected by a differential refractometer is less than the proportion (X2) in the entirety of the polymer component (A).

The lower limit of X1 is preferably 25 mol %, more preferably 30 mol %, and still more preferably 35 mol %. The upper limit of X1 is preferably 60 mol %, more preferably 50 mol %, and still more preferably 45 mol %.

The lower limit of (X2−X1) obtained by subtract X1 from X2 is preferably 0.1 mol %, more preferably 1 mol %, and still more preferably 1.5 mol %. The upper limit of (X2−X1) is preferably 10 mol %, and more preferably 6 mol %.

Inequality (B)

The polymer component (A) satisfies the following inequality (B).

$$\frac{X 2}{X 1} > 1.0 \qquad ( B )$$

In the above inequality (B), X1 and X2 are as defined in the above inequality (A).

The lower limit of a ratio (X2/X1) of X2 to X1 in the above inequality (B) is preferably 1.01, more preferably 1.03, and still more preferably 1.05. The upper limit of X2/X1 is preferably 1.20, and more preferably 1.15.

The lower limit of the molecular weight of a high-molecular weight region of the accumulative area accounting for 1% from the higher-molecular weight side on a gel permeation chromatography elution curve detected by a differential refractometer in the polymer component (A) is preferably 3,000, and more preferably 5,000. The upper limit of the molecular weight is preferably 15,000, and more preferably 10,000.

The lower limit of the proportion of the polymer component (A) contained in the radiation-sensitive resin composition with respect to the total components other than the solvent (D) is preferably 50% by mass, more preferably 60% by mass, and still more preferably 70% by mass.

Synthesis Procedure of Polymer Component (A)

The polymer component (A) may be synthesized by mixing monomers that each give the structural unit (I), the structural unit (II) and as needed other structural unit in an appropriate molar ratio, and polymerizing by a well-known process in the presence of a polymerization initiator such as azobisisobutyronitrile (AIBN), and in the presence of or absence of a chain transfer agent such as 2-cyano-2-propyl dodecyl trithiocarbonate. In a case in which the structural unit (I) is a structural unit derived from hydroxystyrene, hydroxyvinylnaphthalene or the like, these structural units may be formed by, for example, using acetoxy styrene, acetoxy vinylnaphthalene or the like as the monomer to obtain a polymer component, and hydrolyzing the polymer component in the presence of base such as triethylamine. The polymer component (A) may be obtained by mixing a plurality of types of polymers each having the structural unit (I), the structural unit (II) and as needed other structural unit synthesized by the process described above, or the polymer component (A) may be also obtained by mixing a polymer having the structural unit (I) and as needed other structural unit, and a polymer having the structural unit (II) and as needed other structural unit. Furthermore, the polymer component (A) may be also obtained by preparatively collecting using preparative GPC or the like, appropriate portions of the polymer components each having the structural unit (I), the structural unit (II) and as needed the other structural unit which had been synthesized by the aforementioned well-known process.

The polymer component (A) may be obtained by synthesizing through the polymerization by the well-known process described above, and then purifying the resulting polymer component by a well-known procedure. The purification procedure is exemplified by: purification with a solvent, purification through preparative GPC, and the like. Exemplary purification with a solvent includes, for example, adding butyl acetate to dissolve the solid; washing with an aqueous sodium bicarbonate solution; then washing an organic layer with ultra pure water; and then adding a resultant concentrate into hexane to allow coagulation of the polymer, and the like. The purification through preparative GPC includes, for example, using the preparative GPC to remove: a fraction corresponding to a cumulative area accounting for 25% of a total area on the GPC elution curve from a shorter retention time; and a fraction corresponding to a cumulative area accounting for 25% of a total area on the GPC elution curve from a longer retention time, whereby a remainder fraction (a fraction corresponding to a cumulative area accounting for 25% to 75% of the total area on the GPC elution area) is preparatively collected, which is employed as the polymer component (A), and the like.

### (B) Acid Generator

The acid generator (B) is a substance that generates an acid (hereinafter, may be also referred to as “acid (b)”) upon irradiation with a radioactive ray. Examples of the radioactive ray include: electromagnetic waves such as visible light rays, ultraviolet rays, far ultraviolet rays, EUV, X-rays and γ-rays; electron beams, charged particle rays such as a-rays, and the like. The acid (b) generated from the acid generator (B) allows the acid-labile group (a) included in the polymer component (A) to be dissociated, thereby generating a carboxy group, a sulfo group, a phenolic hydroxyl group, etc. As a result, the solubility of the polymer component (A) in the developer solution changes, and thus formation of a resist pattern from the radiation-sensitive resin composition is enabled. The acid generator (B) may be contained in the radiation-sensitive resin composition either in the form of a low-molecular-weight compound (hereinafter, may be also referred to as “(B) acid generating agent” or “acid generating agent (B)”) or in the form of an acid generator so incorporated as a part of the polymer such as the polymer component (A), or may be in both of these forms.

The lower limit of the temperature at which the acid (b) allows the acid-labile group (a) to be dissociated is preferably 80° C., more preferably 90° C., and still more preferably 100° C. The upper limit of the temperature is preferably 130° C., more preferably 120° C., and still more preferably 110° C. The lower limit of the time period for allowing the acid-labile group (a) to be dissociated by the acid (b) is preferably 10 sec, and more preferably 1 min. The upper limit of the time period is preferably 10 min, and more preferably 2 min.

The acid generated from the acid generator (B) is exemplified by a sulfonic acid, an imidic acid, and the like.

The acid generating agent (B) is exemplified by an onium salt compound, an N-sulfonyloxyimide compound, a sulfonimide compound, a halogen-containing compound, a diazo ketone compound, and the like.

Exemplary onium salt compound includes a sulfonium salt, a tetrahydrothiophenium salt, an iodonium salt, a phosphonium salt, a diazonium salt, a pyridinium salt, and the like.

Specific examples of the acid generating agent (B) include compounds disclosed in paragraphs [0080] to [0113] of Japanese Unexamined Patent Application, Publication No. 2009-134088, and the like.

The acid generating agent (B) that generates sulfonic acid upon irradiation with a radioactive ray acid is exemplified by a compound represented by the following formula (3) (hereinafter, may be also referred to as “compound (3)”), and the like. When the acid generating agent (B) has the following structure, it is expected that a diffusion length of the acid (b) generated in the resist film will be more properly reduced through e.g., an interaction with the structural unit (I) of the polymer component (A), or the like, and as a result, more improvements of the inhibitory ability of defects, and the LWR performance of the radiation-sensitive resin composition are enabled.

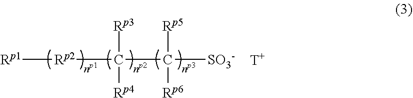

In the above formula (3), R^{p1} represents a monovalent group that includes a ring structure having 5 or more ring atoms; R^{p2} represents a divalent linking group; R^{p3} and R^{p4} each independently represent a hydrogen atom, a fluorine atom, a monovalent hydrocarbon group having 1 to 20 carbon atoms or a monovalent fluorinated hydrocarbon group having 1 to 20 carbon atoms; R^{p5} and R^{p6} each independently represent a fluorine atom or a monovalent fluorinated hydrocarbon group having 1 to 20 carbon atoms; n^{p1} is an integer of 0 to 10; n^{p2} is an integer of 0 to 10; n^{p3} is an integer of 0 to 10, wherein the sum of n^{p1}, n^{p2} and n^{p3} is no less than 1 and no greater than 30, and wherein in a case in which n^{p1} is no less than 2, a plurality of R^{p2}s are each identical or different, in a case in which n^{p2} is no less than 2, a plurality of R^{p3}s are each identical or different and a plurality of R^{p4}s are each identical or different, and in a case in which n^{p3} is no less than 2, a plurality of R^{p3}s are each identical or different and a plurality of R^{p6}s are each identical or different; and T⁺ represents a radiation-sensitive monovalent onium cation.

The monovalent group that includes a ring structure having 5 or more ring atoms which is represented by R^{p1} is exemplified by: a monovalent group that includes an alicyclic structure having 5 or more ring atoms; a monovalent group that includes an aliphatic heterocyclic structure having 5 or more ring atoms; a monovalent group that includes an cyclic structure having 5 or more ring atoms; a monovalent group that includes an aromatic heterocyclic structure having 5 or more ring atoms; and the like.

Examples of the alicyclic structure having 5 or more ring atoms include:

monocyclic saturated alicyclic structures such as a cyclopentane structure, a cyclohexane structure, a cycloheptane structure, a cyclooctane structure, a cyclononane structure, a cyclodecane structure and a cyclododecane structure;

monocyclic unsaturated alicyclic structures such as a cyclopentene structure, a cyclohexene structure, a cycloheptene structure, a cyclooctene structure and a cyclodecene structure;

polycyclic saturated alicyclic structures such as a norbornane structure, an adamantane structure, a tricyclodecane structure and a tetracyclododecane structure;

polycyclic unsaturated alicyclic structures such as a norbornene structure and a tricyclodecene structure; and the like.

Examples of the aliphatic heterocyclic structure having 5 or more ring atoms include:

lactone structures such as a hexanolactone structure and a norbornanelactone structure;

sultone structures such as a hexanosultone structure and a norbornanesultone structure;

oxygen atom-containing heterocyclic structures such as an oxacycloheptane structure and an oxanorbornane structure;

nitrogen atom-containing heterocyclic structures such as an azacyclohexane structure and a diazabicyclooctane structure;

sulfur atom-containing heterocyclic structures such as a thiacyclohexane structure and a thianorbornane structure; and the like.

Examples of the cyclic structure having 5 or more ring atoms include a benzene structure, a naphthalene structure, a phenanthrene structure, an anthracene structure, and the like.

Examples of the aromatic heterocyclic structure having 5 or more ring atoms include:

oxygen atom-containing heterocyclic structures such as a furan structure, a pyran structure, a benzofuran structure and a benzopyran structure;

nitrogen atom-containing heterocyclic structures such as a pyridine structure, a pyrimidine structure and an indole structure; and the like.

The lower limit of the number of ring atoms of the ring structure included in R^{p1} is preferably 6, more preferably 8, still more preferably 9, and particularly preferably 10. The upper limit of the number of ring atoms is preferably 15, more preferably 14, still more preferably 13, and particularly preferably 12. When the number of ring atoms falls within the above range, the aforementioned diffusion length of the acid may be further properly reduced, and as a result, more improvements of the LWR performances, etc., of the radiation-sensitive resin composition are enabled.

A part or all of hydrogen atoms included in the ring structure of R^{p1} may be substituted with a substituent. Examples of the substituent include halogen atoms such as a fluorine atom, a chlorine atom, a bromine atom and an iodine atom, a hydroxy group, a carboxy group, a cyano group, a nitro group, an alkoxy group, an alkoxycarbonyl group, an alkoxycarbonyloxy group, an acyl group, an acyloxy group, and the like. Of these, the hydroxy group is preferred.

R^{p1} represents preferably a monovalent group that includes an alicyclic structure having 5 or more ring atoms or a monovalent group that includes an aliphatic heterocyclic structure having 5 or more ring atoms, more preferably a monovalent group that includes an alicyclic structure having 9 or more ring atoms or a monovalent group that includes an aliphatic heterocyclic structure having 9 or more ring atoms, still more preferably an adamantyl group, a hydroxyadamantyl group, a norbornanelactone-yl group, a norbornanesultone-yl group or a 5-oxo-4-oxatricyclo[4.3.1.1^{3,8}]undecan-yl group, and particularly preferably an adamantyl group.

Examples of the divalent linking group represented by R^{p2} include a carbonyl group, an ether group, a carbonyloxy group, a sulfide group, a thiocarbonyl group, a sulfonyl group, a divalent hydrocarbon group, and the like. Of these, the carbonyloxy group, the sulfonyl group, an alkanediyl group or a divalent alicyclic saturated hydrocarbon group is preferred, the carbonyloxy group or the divalent alicyclic saturated hydrocarbon group is more preferred, the carbonyloxy group or a norbornanediyl group is still more preferred, and the carbonyloxy group is particularly preferred. It is to be noted that in a case in which R^{p2} represents the carbonyloxy group, orientation of the carbonyloxy group is not particularly limited. More specifically, a carbonyl carbon atom of the carbonyloxy group may bond to R^{p1}, or an oxy-oxygen atom may bond to R^{p1}.

The monovalent hydrocarbon group having 1 to 20 carbon atoms which may be represented by R^{p3} or R^{p4} is exemplified by an alkyl group having 1 to 20 carbon atoms, and the like. The monovalent fluorinated hydrocarbon group having 1 to 20 carbon atoms which may be represented by R^{p3} or R^{p4} is exemplified by a fluorinated alkyl group having 1 to 20 carbon atoms, and the like. R^{p3} and R^{p4} each independently represent preferably a hydrogen atom, a fluorine atom or a fluorinated alkyl group, more preferably a fluorine atom or a perfluoroalkyl group, and still more preferably a fluorine atom or a trifluoromethyl group.

The monovalent fluorinated hydrocarbon group having 1 to 20 carbon atoms which may be represented by R^{p5} or R^{p6} is exemplified by a fluorinated alkyl group having 1 to 20 so carbon atoms, and the like. R^{p5} and R^{p6} each independently represent preferably a fluorine atom or a fluorinated alkyl group, more preferably a fluorine atom or a perfluoroalkyl group, still more preferably a fluorine atom or a trifluoromethyl group, and particularly preferably a fluorine atom.

In the above formula (3), n^{p1} is preferably 0 to 5, more preferably 0 to 3, still more preferably 0 to 2, and particularly preferably 0 or 1.

In the above formula (3), n^{p2} is preferably 0 to 5, more preferably 0 to 2, still more preferably 0 or 1, and particularly preferably 0.

The lower limit of n^{p3} is preferably 1, and more preferably 2. When n^{p3} is no less than 1, the strength of the acid generated from the compound (3) may be increased, and consequently the inhibitory ability of defects, and the LWR performance of the radiation-sensitive resin composition may be more improved. The upper limit of n^{p3} is preferably 4, more preferably 3, and still more preferably 2.

The lower limit of the sum of n^{p1}, n^{p2} and n^{p3}, i.e., (nₚ₁+n^{p2}+n^{p3}), is preferably 2, and more preferably 4. The upper limit of the sum of n^{p1}, n^{p2} and n^{p3} is preferably 20, and more preferably 10.

Examples of the radiation-sensitive monovalent onium cation represented by T⁺ include a cation represented by the following formula (r-a) (hereinafter, may be also referred to as “cation (r-a)”), a cation represented by the following formula (r-b) (hereinafter, may be also referred to as “cation (r-b)”), a cation represented by the following formula (r-c) (hereinafter, may be also referred to as “cation (r-c)”), and the like.

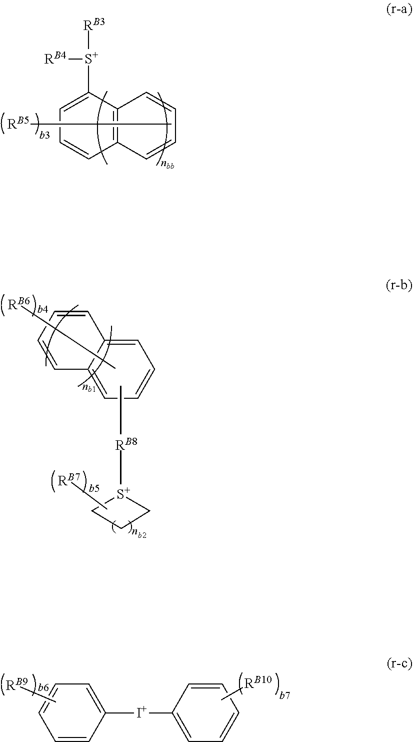

In the above formula (r-a), R^{B3} and R^{B4} each independently represent a monovalent organic group having 1 to 20 carbon atoms; b3 is an integer of 0 to 11, wherein in a case where b3 is 1, R^{B5} represents a monovalent organic group having 1 to 20 carbon atoms, a hydroxy group, a nitro group or a halogen atom, in a case where b3 is no less than 2, a plurality of R^{B5}s are each identical or different, and represent a monovalent organic group having 1 to 20 carbon atoms, a hydroxy group, a nitro group or a halogen atom, or the plurality of R^{B5}s taken together represent a part of a ring structure having 4 to 20 ring atoms together with the carbon chain to which the plurality of R^{B5}s bond; and n_{bb} is an integer of 0 to 3.

The monovalent organic group having 1 to 20 carbon atoms which may be represented by R^{B3}, R^{B4} or R^{B5} is exemplified by a monovalent hydrocarbon group having 1 to 20 carbon atoms, a monovalent group (g) that includes a divalent hetero atom-containing group between two adjacent carbon atoms or at the end of the atomic bonding side of the so monovalent hydrocarbon group; a monovalent group obtained from the monovalent hydrocarbon group or the group (g) by substituting with a hetero atom-containing group a part or all of hydrogen atoms included therein; or the like.

R^{B3} and R^{B4} each represent preferably a monovalent unsubstituted hydrocarbon group having 1 to 20 carbon atoms or a hydrocarbon group obtained therefrom by substituting a hydrogen atom included therein with a substituent, more preferably a monovalent unsubstituted aromatic hydrocarbon group having 6 to 18 carbon atoms or an aromatic hydrocarbon group obtained therefrom by substituting a hydrogen atom included therein with a substituent, still more preferably a substituted or unsubstituted phenyl group, and particularly preferably an unsubstituted phenyl group.

The substituent which may substitute for the hydrogen atom included in the monovalent hydrocarbon group having 1 to 20 carbon atoms which may be represented by R^{B3} or R^{B4} is preferably a substituted or unsubstituted monovalent hydrocarbon group having 1 to 20 carbon atoms, —OSO₂—R^{k}, —SO₂—R^{k}, —OR^{k}, —COOR^{k}, —O—CO—R^{k}, —O—R^{kk}—COOR^{k}, —R^{kk}—CO—R^{k} or —S—R^{k}, wherein R^{k} represents a monovalent hydrocarbon group having 1 to 10 carbon atoms; and R^{kk} represents a single bond or a divalent hydrocarbon group having 1 to 10 carbon atoms.

R^{B5} represents preferably a substituted or unsubstituted monovalent hydrocarbon group having 1 to 20 carbon atoms, —OSO₂—R^{k}, —SO₂—R^{k}, —OR^{k}, —COOR^{k}, —O—CO—R^{k}, —O—R^{kk}—COOR^{k}, —R^{kk}—CO—R^{k} or —S—R^{k}, wherein R^{k} represents a monovalent hydrocarbon group having 1 to 10 carbon atoms; and R^{kk} represents a single bond or a divalent hydrocarbon group having 1 to 10 carbon atoms.

In the above formula (r-b), b4 is an integer of 0 to 9; wherein in a case in which b4 is 1, R^{B6} represents a monovalent organic group having 1 to 20 carbon atoms, a hydroxy group, a nitro group or a halogen atom, and in a case in which b4 is no less than 2, a plurality of R^{B6}s are each identical or different and represent a monovalent organic group having 1 to 20 carbon atoms, a hydroxy group, a nitro group or a halogen atom, or the plurality of R^{B6}s taken together represent a part of a ring structure having 4 to 20 ring atoms together with the carbon chain to which the plurality of R^{B6}s bond; b5 is an integer of 0 to 10, wherein in a case in which b5 is 1, R^{B7} represents a monovalent organic group having 1 to 20 carbon atoms, a hydroxy group, a nitro group or a halogen atom, and in a case in which b5 is no less than 2, a plurality of R^{B7}s are each identical or different and represent a monovalent organic group having 1 to 20 carbon atoms, a hydroxy group, a nitro group or a halogen atom, or the plurality of R^{B7}s taken together represent a part of a ring structure having 3 to 20 ring atoms taken together with the carbon atom or carbon chain to which the plurality of R^{B7}s bond; n_{b2} is an integer of 0 to 3; R^{B8} represents a single bond or a divalent organic group having 1 to 20 carbon atoms; and n_{b1} is an integer of 0 to 2.

R^{B6} and R^{B7} each represent preferably a substituted or unsubstituted monovalent hydrocarbon group having 1 to 20 carbon atoms, —OR^{k}, —COOR^{k}, —O—CO—R^{k}, —O—R^{kk}—COOR^{k} or —R^{kk}—CO—R^{k}, wherein R^{k} represents a monovalent hydrocarbon group having 1 to 10 carbon atoms; and R^{kk} represents a single bond or a divalent hydrocarbon group having 1 to 10 carbon atoms.

In the above formula (r-c), b6 is an integer of 0 to 5, wherein in a case in which b6 is 1, R^{B9} represents a monovalent organic group having 1 to 20 carbon atoms, a hydroxy group, a nitro group or a halogen atom, in a case in which b6 is no less than 2, a plurality of R^{B9}s are each identical or different and represent a monovalent organic group having 1 to 20 carbon atoms, a hydroxy group, a nitro group or a halogen atom, or the plurality of R^{B9}s taken together represent a part of a ring structure having 4 to 20 ring atoms together with the carbon chain to which the plurality of R^{B9}s bond; and b7 is an integer of 0 to 5, wherein in a case in which b7 is 1, R^{B10} represents a monovalent organic group having 1 to 20 carbon atoms, a so hydroxy group, a nitro group or a halogen atom, and in a case in which b7 is no less than 2, a plurality of R^{B10}s are each identical or different and represent a monovalent organic group having 1 to 20 carbon atoms, a hydroxy group, a nitro group or a halogen atom, or the plurality of R^{B10}s taken together represent a part of a ring structure having 4 to 20 ring atoms together with the carbon chain to which the plurality of R^{B10}s bond.

R^{B9} and R^{B10} each represent preferably a substituted or unsubstituted monovalent hydrocarbon group having 1 to 20 carbon atoms, —OSO₂—R^{k}, —SO₂—R^{k}, —OR^{k}, —COOR^{k}, —O—CO—R^{k}, —O—R^{kk}—COOR^{k}, —R^{kk}—CO—R^{k}, —S—R^{k}, or a ring structure taken together represented by at least two of R^{a7} and R^{a8}, wherein R^{k} represents a monovalent hydrocarbon group having 1 to 10 carbon atoms; and R^{kk} represents a single bond or a divalent hydrocarbon group having 1 to 10 carbon atoms.

Examples of the monovalent hydrocarbon group having 1 to 20 carbon atoms which may be represented by R^{B5}, R^{B6}, R^{B7}, R^{B9} or R^{B10} include:

linear alkyl groups such as a methyl group, an ethyl group, a n-propyl group and a n-butyl group;

branched alkyl groups such as an i-propyl group, an i-butyl group, a sec-butyl group and a t-butyl group;

aryl groups such as a phenyl group, a tolyl group, a xylyl group, a mesityl group and a naphthyl group;

aralkyl groups such as a benzyl group and a phenethyl group; and the like.

Examples of the divalent organic group which may be represented by R^{B8} include groups obtained by removing one hydrogen atom from the monovalent organic group having 1 to 20 carbon atoms exemplified in connection with R^{B3}, R^{B4} or R^{B5} in the above formula (r-a), and the like.

Examples of the substituent which may substitute for the hydrogen atom included in the hydrocarbon group which may be represented by R^{B5}, R^{B6}, R^{B7}, R^{B9} or R^{B10} include halogen atoms such as a fluorine atom, a chlorine atom, a bromine atom and an iodine atom, a hydroxy group, a carboxy group, a cyano group, a nitro group, an alkoxy group, an alkoxycarbonyl group, an alkoxycarbonyloxy group, an acyl group, an acyloxy group, and the like. Of these, the halogen atom is preferred, and a fluorine atom is more preferred.

R^{B5}, R^{B6}, R^{B7}, R^{B9} and R^{B10} each represent preferably an unsubstituted linear or branched monovalent alkyl group, a monovalent fluorinated alkyl group, an unsubstituted monovalent aromatic hydrocarbon group, —OSO₂—R^{k} or —SO₂—R^{k}, more preferably a fluorinated alkyl group or an unsubstituted monovalent aromatic hydrocarbon group, and still more preferably a fluorinated alkyl group.

In the formula (r-a), b3 is preferably 0 to 2, more preferably 0 or 1, and still more preferably 0; and n_{bb} is preferably 0 or 1, and more preferably 0. In the formula (r-b), b4 is preferably 0 to 2, more preferably 0 or 1, and still more preferably 0; b5 is preferably 0 to 2, more preferably 0 or 1, and still more preferably 0; n_{b2} is preferably 2 or 3, and more preferably 2; and n_{b1} is preferably 0 or 1, and more preferably 0. In the formula (r-c), b6 and b7 are preferably 0 to 2, more preferably 0 or 1, and still more preferably 0.

Of these, T⁺ represents preferably the cation (r-a), and more preferably a triphenylsulfonium cation.

Examples of the acid generating agent (B) include: as the acid generating agent that generates sulfonic acid, compounds represented by the following formulae (3-1) to (3-20) (hereinafter, may be also referred to as “compounds (3-1) to (3-20)”); as the acid generating agent that generates imidic acid, compounds represented by the following formulae (4-1) to (4-3) (hereinafter, may be also referred to as “compounds (4-1) to (4-3)”); and the like.

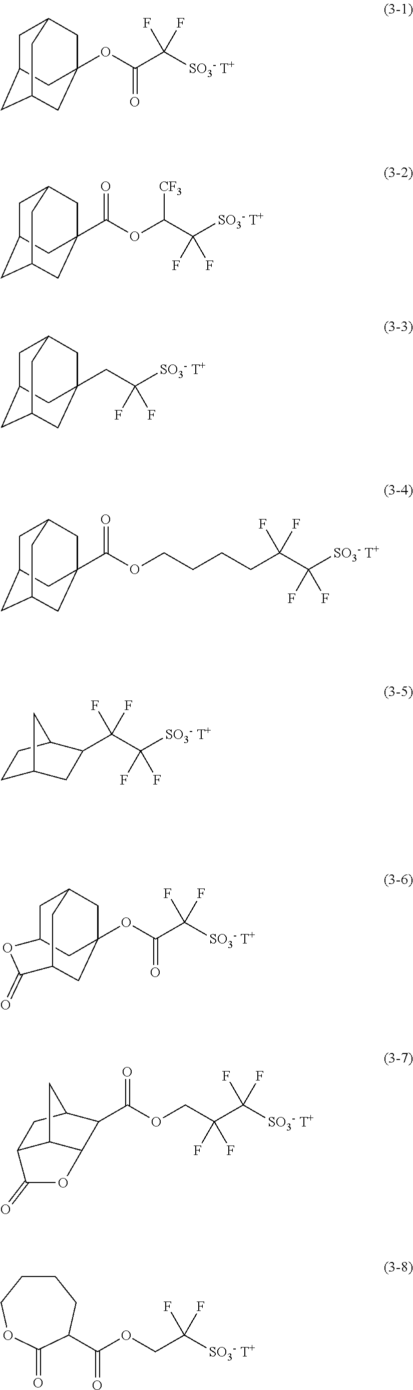

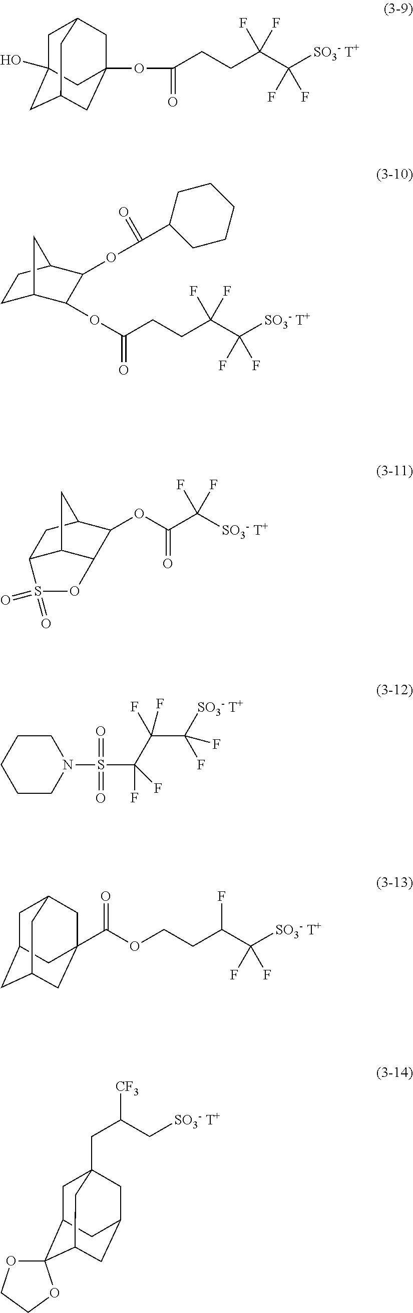

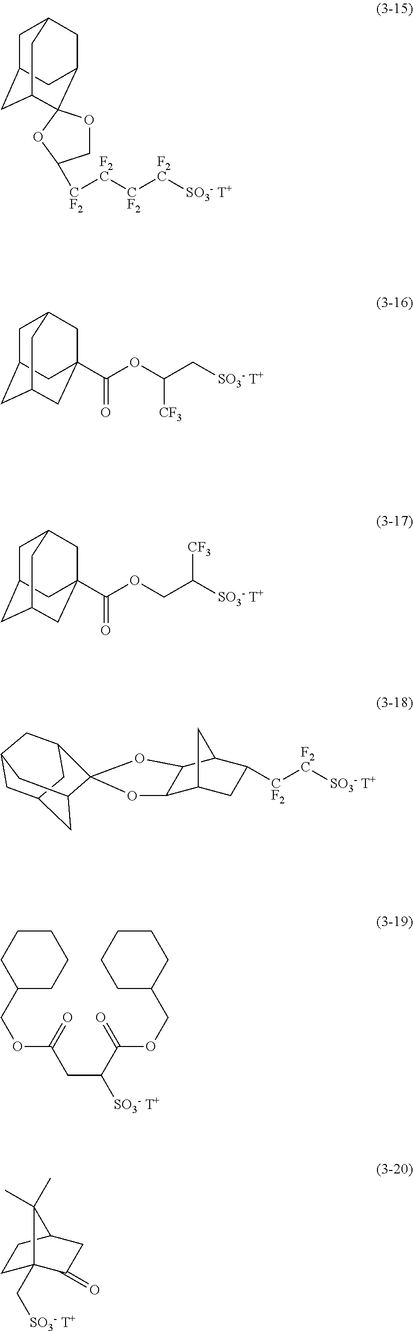

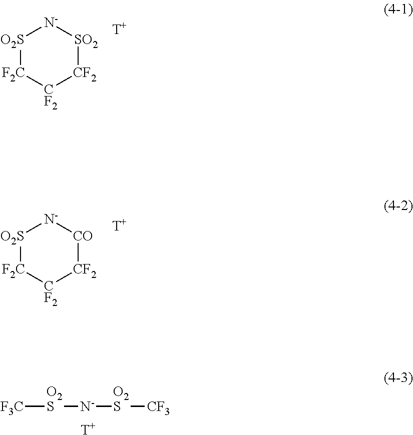

In the above formulae (3-1) to (3-20) and (4-1) to (4-3), T represents a radiation-sensitive monovalent onium cation.

Furthermore, the acid generator (B) is exemplified by a polymer in which a structure of the acid generator is incorporated as a part of the polymer component (A), such as a polymer having a structural unit represented by the following formula (3′).

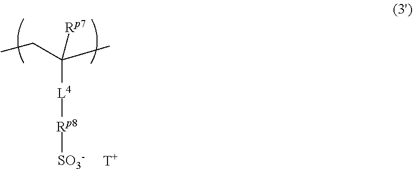

In the above formula (3′), R^{p7} represents a hydrogen atom or a methyl group; L⁴ represents a single bond, —COO— or a divalent carbonyloxyhydrocarbon group; R^{p8} represents a fluorinated alkanediyl group having 1 to 10 carbon atoms; and T⁺ represents a radiation-sensitive monovalent onium cation. It is to be noted that in a case in which L⁴ represents —COO— or a divalent carbonyloxyhydrocarbon group, the carbonyl carbon atom of such a group bonds to the carbon atom to which R^{p7} bonds.

In light of a degree of copolymerization of a monomer that gives the structural unit represented by the above formula (3′), R^{p7} represents preferably a methyl group.

L⁴ represents preferably a divalent carbonyloxyhydrocarbon group, and more preferably a carbonyloxyalkanediyl group or a carbonyloxyalkanediylarenediyl group.

R^{p8} represents preferably a fluorinated alkanediyl group having 1 to 4 carbon atoms, more preferably a perfluoroalkanediyl group having 1 to 4 carbon atoms, and still more preferably a hexafluoropropanediyl group.

The acid generating agent (B) is preferably the compound (3), and more preferably the compound (3-2), (3-11), (3-12), (3-13), (3-15) or (3-20).

In a case in which the acid generator (B) is the acid generating agent (B), the lower limit of the content of the acid generating agent (B) with respect to 100 parts by mass of the polymer component (A) is preferably 0.1 parts by mass, more preferably 1 part by mass, still more preferably 5 parts by mass, and particularly preferably 10 parts by mass. The upper limit of the content of the acid generating agent (B) is preferably 50 parts by mass, more preferably 40 parts by mass, still more preferably 30 parts by mass, and particularly preferably 25 parts by mass. When the content of the acid generating agent (B) falls within the above range, sensitivity and developability the radiation-sensitive resin composition may be improved, and consequently the inhibitory ability of defects, and the LWR performance can be more improved. One, or two or more types of the acid generator (B) may be contained.

### (C) Acid Diffusion Controller

The acid diffusion controller (C) controls a phenomenon of diffusion of the acid, which was generated from the acid generator (B), etc. upon the exposure, in the resist film, whereby the effect of inhibiting unwanted chemical reactions in an unexposed region is exhibited. In addition, the storage stability of the radiation-sensitive resin composition is improved and the resolution thereof as a resist is more improved. Moreover, variation of the line width of the resist pattern caused by variation of post-exposure time delay from the exposure until a development treatment can be suppressed, which enables the radiation-sensitive resin composition with superior process stability to be obtained. The acid diffusion controller (C) may be contained in the radiation-sensitive resin composition in the form of a low-molecular weight compound (hereinafter, may be also referred to as “(C) acid diffusion control agent” or “acid diffusion control agent (C)” as appropriate) or in the form incorporated as a part of the polymer, or may be in both of these forms.

The acid diffusion control agent (C) is exemplified by a nitrogen atom-containing compound, a photolabile base that generates a weak acid through photosensitization upon an exposure, and the like.

Examples of the nitrogen atom-containing compound include: amine compounds such as tripentylamine and trioctylamine; amide group-containing compounds such as formamide and N,N-dimethylacetamide; urea compounds such as urea and 1,1-dimethylurea; nitrogen-containing heterocyclic compounds such as pyridine, N-(undecylcarbonyloxyethyl)morpholine and N-t-pentyloxycarbonyl-4-hydroxypiperidine; and the like.

The photolabile base is exemplified by a compound that includes an anion of a weak acid, and an onium cation that is degradable upon an exposure, and the like. The photolabile base generates in a light-exposed region, a weak acid from: a proton produced through degradation of the onium cation; and the anion of the weak acid, and thus the acid diffusion controllability is lowered.

Examples of the photolabile base include compounds represented by the following formulae, the compound represented by the above formula (3) (wherein, n^{p3} is 0; and R^{p3} and R^{p4} each independently represent a hydrogen atom or a monovalent hydrocarbon group having 1 to 20 carbon atoms), and the like.

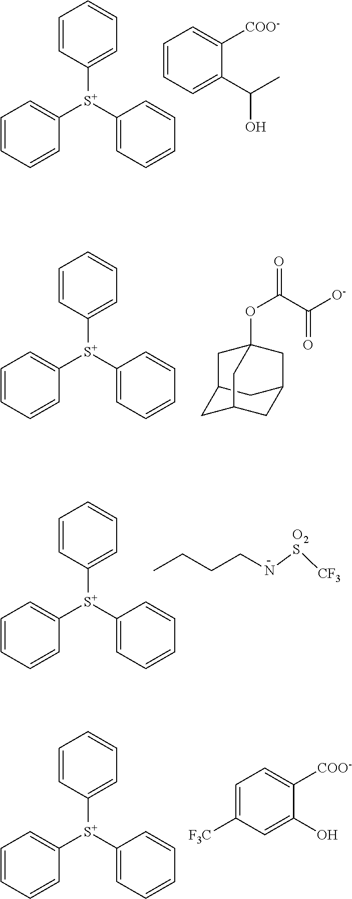

In a case in which the radiation-sensitive resin composition contains the acid diffusion control agent (C), the lower limit of the acid diffusion control agent (C) with respect to 100 parts by mass of the polymer component (A) is preferably 0.1 parts by mass, more so preferably 0.5 parts by mass, and still more preferably 1 part by mass. The upper limit of the content of the acid diffusion control agent (C) is preferably 20 parts by mass, more preferably 10 parts by mass, and still more preferably 5 parts by mass.

In a case in which the radiation-sensitive resin composition contains the acid diffusion control agent (C), the lower limit of the content of the acid diffusion control agent (C) with respect to 100 mol % of the acid generating agent (B) is preferably 1 mol %, more preferably 5 mol %, and still more preferably 10 mol %. The upper limit of the content of the acid diffusion control agent (C) is preferably 250 mol %, more preferably 150 mol %, and still more preferably 100 mol %.

When the content of the acid diffusion control agent falls within the above range, more improvements of the inhibitory ability of defects, and the LWR performance of the radiation-sensitive resin composition are enabled. One, or two or more types of the acid diffusion controller (C) may be contained.

### (D) Solvent

The radiation-sensitive resin composition typically contains the solvent (D). The solvent (D) is not particularly limited as long as it is a solvent capable of dissolving or dispersing at least the polymer component (A) and the acid generator (B), as well as the optional component which may be contained as desired.

The solvent (D) is exemplified by an alcohol solvent, an ether solvent, a ketone solvent, an amide solvent, an ester solvent, a hydrocarbon solvent, and the like.

Examples of the alcohol solvent include:

aliphatic monohydric alcohol solvents having 1 to 18 carbon atoms such as 4-methyl-2-pentanol and n-hexanol;

alicyclic monohydric alcohol solvents having 3 to 18 carbon atoms such as cyclohexanol;

polyhydric alcohol solvents having 2 to 18 carbon atoms such as 1,2-propylene glycol;

polyhydric alcohol partial ether solvents having 3 to 19 carbon atoms such as 1-methoxy-2-propanol; and the like.

Examples of the ether solvent include:

dialkyl ether solvents such as diethyl ether, dipropyl ether, dibutyl ether, dipentyl ether, diisoamyl ether, dihexyl ether and diheptyl ether;

cyclic ether solvents such as tetrahydrofuran and tetrahydropyran;

aromatic ring-containing ether solvents such as diphenyl ether and anisole; and the like.

Examples of the ketone solvent include:

chain ketone solvents such as acetone, methyl ethyl ketone, methyl n-propyl ketone, methyl n-butyl ketone, diethyl ketone, methyl iso-butyl ketone, 2-heptanone, ethyl n-butyl ketone, methyl n-hexyl ketone, di-iso-butyl ketone and trimethylnonanone;

cyclic ketone solvents such as cyclopentanone, cyclohexanone, cycloheptanone, cyclooctanone and methylcyclohexanone;

2,4-pentanedione, acetonylacetone and acetophenone; and the like.

Examples of the amide solvent include:

cyclic amide solvents such as N,N′-dimethylimidazolidinone and N-methylpyrrolidone;

chain amide solvents such as N-methylformamide, N,N-dimethylformamide, N,N-diethylformamide, acetamide, N-methyl acetamide, N,N-dimethyl acetamide and N-methylpropionamide; and the like.

Examples of the ester solvent include:

monocarboxylic acid ester solvents such as n-butyl acetate and ethyl lactate;

polyhydric alcohol carboxylate solvents such as propylene glycol acetate;

polyhydric alcohol partial ether carboxylate solvents such as propylene glycol monomethyl ether acetate;

polyhydric carboxylic acid diester solvents such as diethyl oxalate;

carbonate solvents such as dimethyl carbonate and diethyl carbonate; and the like.

Examples of the hydrocarbon solvent include:

aliphatic hydrocarbon solvents having 5 to 12 carbon atoms such as n-pentane and n-hexane;

aromatic hydrocarbon solvents having 6 to 16 carbon atoms such as toluene and xylene; and the like.

Of these, the ester solvent and/or the ketone solvent are/is preferred, the polyhydric alcohol partial ether carboxylate solvent and/or the cyclic ketone solvent are/is more preferred, and propylene glycol monomethyl ether acetate and/or cyclohexanone are/is still so more preferred. One, or two or more types of the solvent (D) may be contained.

### Other Optional Component

The other optional component is exemplified by a surfactant, and the like. The radiation-sensitive resin composition may contain one, or two or more types of each of the other optional component.

The surfactant exerts the effect of improving the coating property, striation, developability, and the like. Examples of the surfactant include: nonionic surfactants such as polyoxyethylene lauryl ether, polyoxyethylene stearyl ether, polyoxyethylene oleyl ether, polyoxyethylene n-octylphenyl ether, polyoxyethylene n-nonylphenyl ether, polyethylene glycol dilaurate and polyethylene glycol distearate; and the like. Examples of the commercially available product of the surfactant include KP341 (Shin-Etsu Chemical Co., Ltd.), Polyflow No. 75 and Polyflow No. 95 (all available from Kyoeisha Chemical Co., Ltd.), EFTOP EF301, EFTOP EF303 and EFTOP EF352 (all available from Tochem Products Co. Ltd.), Megaface F171 and Megaface F173 (all available from DIC, Corporation), Fluorad FC430 and Fluorad FC431 (all available from Sumitomo 3M Limited), ASAHI GUARD AG710, Surflon S-382, Surflon SC-101, Surflon SC-102, Surflon SC-103, Surflon SC-104, Surflon SC-105 and Surflon SC-106 (all available from Asahi Glass Co., Ltd.), and the like.

In a case in which the radiation-sensitive resin composition contains the surfactant, the upper limit of the content of the surfactant with respect to 100 parts by mass of the polymer component (A) is preferably 2 parts by mass. The lower limit of the content is, for example, 0.1 parts by mass.

### Preparation Procedure of Radiation-Sensitive Resin Composition

The radiation-sensitive resin composition may be prepared, for example, by mixing the polymer component (A), the acid generator (B) and the solvent (D), as well as the optional component which is added as needed such as the acid diffusion controller (C) in a certain ratio, and preferably filtrating the resulting mixture through a membrane filter having a pore size of about 0.2 μm.

The radiation-sensitive resin composition may be used either for positive-tone pattern formation conducted using an alkaline developer solution, or for negative-tone pattern formation conducted using an organic solvent-containing developer solution.

### Resist Pattern-Forming Method

The resist pattern-forming method according to another embodiment of the present invention includes: the step of applying directly or indirectly on a substrate the radiation-sensitive resin composition of the embodiment of the invention (hereinafter, may be also referred to as “applying step”); the step of exposing the resist film formed by the applying step (hereinafter, may be also referred to as “exposure step”); and the step of developing the resist film exposed (hereinafter, may be also referred to as “development step”).

Since the radiation-sensitive resin composition of the one embodiment of the present invention described above is used in the resist pattern-forming method, formation of a resist pattern being accompanied by less LWR and fewer defects is enabled, with the sensitivity being maintained. Each step will be described below.

Applying Step

In this step, the radiation-sensitive resin composition is applied directly or indirectly on the substrate. Thus, a resist film is formed. The substrate is exemplified by a conventionally well-known substrate such as a silicon wafer, a wafer coated with silicon dioxide or aluminum, and the like. In addition, the case in which the radiation-sensitive resin composition is applied directly on the substrate may involve, for example, applying the radiation-sensitive resin composition on an antireflective film formed on the substrate, and the like. Such an antireflective film is exemplified by an organic or inorganic antireflective film disclosed in, for example, Japanese Examined Patent Application, Publication No. H6-12452, Japanese Unexamined Patent Application, Publication No. S59-93448, and the like. An application procedure is exemplified by spin-coating, cast coating, roll-coating, and the like. After the application, prebaking (PB) may be carried out as needed for evaporating the solvent remaining in the coating film. The lower limit of the temperature for PB is preferably 60° C., and more preferably 80° C. The upper limit of the temperature for PB is preferably 150° C., and more preferably 140° C. The lower limit of the time period for PB is preferably 5 sec, and more preferably 10 sec. The lower limit of the time period for PB is preferably 600 sec, and more preferably 300 sec. The lower limit of the average thickness of the resist film formed is preferably 10 nm, and more preferably 20 nm. The upper limit of the average thickness is preferably 1,000 nm, and more preferably 500 nm.

Exposure Step

In this step, the resist film formed by the applying step is exposed. This exposure is carried out by irradiation with an exposure light through a photomask (as the case may be, through a liquid immersion medium such as water). Examples of the exposure light include electromagnetic waves such as visible light rays, ultraviolet rays, far ultraviolet rays, EUV, X-rays and y-rays; charged particle rays such as electron beams and a-rays, and the like, which may be selected in accordance with a line width, etc., of the intended pattern. Of these, far ultraviolet rays, EUV or electron beams is preferred; an ArF excimer laser beam (wavelength: 193 nm), a KrF excimer laser beam (wavelength: 248 nm), EUV or an electron beam is more preferred; an ArF excimer laser beam, EUV or an electron beam is still more preferred; and EUV or an electron beam is particularly preferred.

It is preferred that post exposure baking (PEB) is carried out after the exposure to promote dissociation of the acid-labile group (a) included in the polymer component (A), etc. mediated by the acid generated from the acid generator (B), etc., upon the exposure in exposed regions of the resist film. This PEB enables a difference in solubility of the resist film in a developer solution between the light-exposed regions and light-unexposed regions to be increased. The lower limit of the temperature for PEB is preferably 50° C., more preferably 80° C., and still more preferably 100° C. The upper limit of the temperature is preferably 180° C., and more preferably 130° C. The lower limit of the time period for PEB is preferably 5 sec, more preferably 10 sec, and still more preferably 30 sec. The upper limit of the time period is preferably 600 sec, more preferably 300 sec, and still more preferably 100 sec.

Development Step

In this step, the resist film exposed is developed. Accordingly, formation of a predetermined resist pattern is enabled. After the development, washing with a rinse agent such as water or an alcohol, followed by drying is typically carried out. The development procedure in the development step may be carried out by either development with an alkali, or development with an organic solvent.

In the case of the development with an alkali, the developer solution for use in the development is exemplified by alkaline aqueous solutions prepared by dissolving at least one alkaline compound such as sodium hydroxide, potassium hydroxide, sodium carbonate, sodium silicate, sodium metasilicate, aqueous ammonia, ethylamine, n-propylamine, diethylamine, di-n-propylamine, triethylamine, methyldiethylamine, ethyldimethylamine, triethanolamine, tetramethylammonium hydroxide (TMAH), pyrrole, piperidine, choline, 1,8-diazabicyclo-[5.4.0]-7-undecene, 1,5-diazabicyclo-[4.3.0]-5-nonene, etc., and the like. Of these, an aqueous TMAH solution is preferred, and a 2.38% by mass aqueous TMAH solution is more preferred.

In the case of the development with an organic solvent, the developer solution is exemplified by: an organic solvent such as a hydrocarbon solvent, an ether solvent, an ester solvent, a ketone solvent and an alcohol solvent; a solvent containing the organic solvent; and the like. Exemplary organic solvent includes one, or two or more types of the solvents exemplified as the solvent (D) for the radiation-sensitive resin composition, and the like. Of these, the ester solvent or the ketone solvent are preferred. The ester solvent is preferably an acetic acid ester solvent, and more preferably n-butyl acetate. The ketone solvent is preferably a chain ketone, and more preferably 2-heptanone. The lower limit of the content of the organic solvent in the developer solution is preferably 80% by mass, more preferably 90% by mass, still more preferably 95% by mass, and particularly preferably 99% by mass. Components other than the organic solvent in the organic solvent developer solution are exemplified by water, silicone oil, and the like.

Examples of the development procedure include: a dipping procedure in which the substrate is immersed for a given time period in the developer solution charged in a container; a puddle procedure in which the developer solution is placed to form a dome-shaped bead by way of the surface tension on the surface of the substrate for a given time period to conduct a development; a spraying procedure in which the developer solution is sprayed onto the surface of the substrate; a dynamic dispensing procedure in which the developer solution is continuously applied onto the substrate that is rotated at a constant speed while scanning with a developer solution-application nozzle at a constant speed; and the like.

Examples of the pattern to be formed by the resist pattern-forming method include a line-and-space pattern, a hole pattern, and the like.

### Polymer Composition

The polymer composition contains the polymer component (A). As referred to herein, the “polymer composition” involves not only a mixture of a plurality of types of polymers, but also one type of polymer. The polymer component (A) is as described above as the polymer component (A) contained in the radiation-sensitive resin composition.

### EXAMPLES

Hereinafter, the present invention is explained in detail by way of Examples, but the present invention is not in any way limited to these Examples. Physical property values in Examples were measured as described below.

Weight-Average Molecular Weight (Mw), Number-Average Molecular Weight (Mn) and Dispersity Index (Mw/Mn)

The Mw and the Mn of the polymer component were determined by gel permeation chromatography (GPC) using GPC columns (“G2000 HXL” x 2, “G3000 HXL” x 1 and “G4000 HXL” x 1, Tosoh Corporation) under the analytical conditions involving a flow rate: 1.0 mL/min, an elution solvent: tetrahydrofuran, a sample concentration: 1.0% by mass, an amount of injected sample: 100 μL, a column temperature: 40° C., and a detector: differential refractometer, with mono-dispersed polystyrene as a standard. Furthermore, the dispersity index (Mw/Mn) was calculated from the results of the determination of the Mw and the Mn.

Measurement of X1 and X2

By using preparative GPC columns (“JAIGEL 2.5H+2H” available from Japan Analytical Industry Co., Ltd.) a fraction that corresponds to an area accounting for 1% from a shorter retention time was preparatively collected under analytical conditions involving: a flow rate of 4.0 mL/min; an elution solvent of tetrahydrofuran: a sample concentration of 3% by mass; an amount of injected sample of 3 mL; a column temperature of 40° C.; and a detector being a differential refractometer, and then by using PyGC-MS available from Agilent Technologies, Ltd., an area ratio of each monomer that gives each structural unit was calculated on the polymer component included in the fraction preparatively collected. Of the area ratio of each monomer, the area ratio of the hydroxystyrene unit was decided as X1 (mol %). Meanwhile, an area ratio of the hydroxystyrene unit determined by a similar analysis on PyGC-MS for the entire polymer component without carrying out the preparative collection was decided as X2 (mol %).

### Synthesis of Polymer Component (A)

Monomers used in syntheses of the polymer components (A) are presented below.

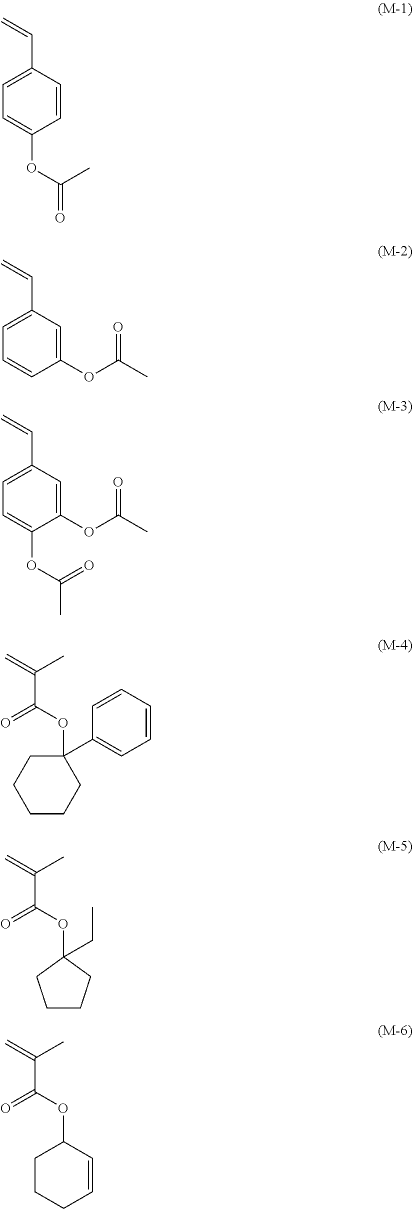

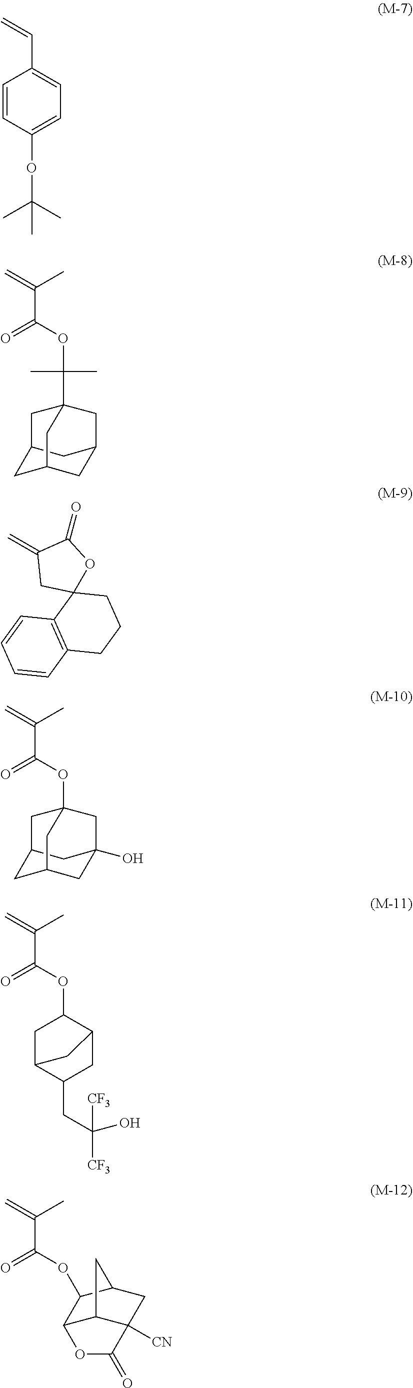

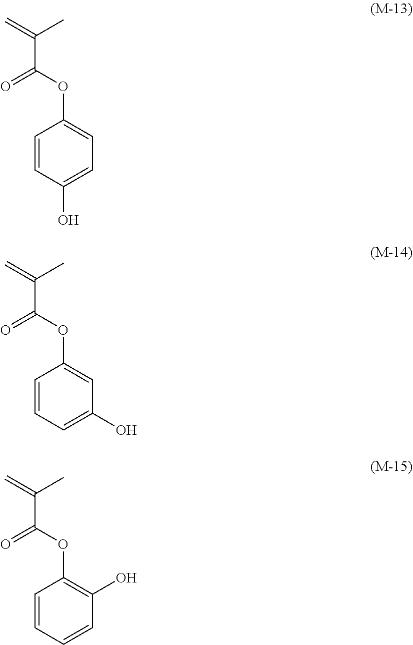

In Examples described below, unless otherwise specified particularly, values in terms of parts by mass are based on total mass of the monomer(s) used which was assumed to be 100 parts by mass, and values in terms of mol % are based on total number of moles of the monomer(s) used which was assumed to account for 100 mol %.

### Example 1

### Synthesis of Polymer Component (A-1)

The monomer (M-1), the monomer (M-4) and the monomer (M-9) were dissolved in 60 parts by mass of 1-methoxy-2-propanol such that the proportion of each structural unit contained in a polymer finally obtained (molar ratio) of 35/45/20 was attained. Next, as a chain transfer agent, 3.5 mol % 2-cyano-2-propyl dodecyl trithiocarbonate with respect to total monomers, and as a polymerization initiator, 0.7 mol % azobisisobutyronitrile (AIBN) with respect to total monomers were added to prepare a monomer solution. After the monomer solution was purged with nitrogen for 30 min, the monomer solution was heated with stirring to elevate the temperature to 80° C. A time point at which the temperature of the monomer solution was elevated to 80° C. was regarded as the time point of the start of the polymerization reaction, and the polymerization reaction was performed for 6 hrs. After completion of the polymerization reaction, a solution prepared by dissolving 14.3 mol % AIBN with respect to total monomers, and 17.8 mol % tert-dodecanethiol with respect to total monomers in 50 parts by mass of 1-methoxy-2-propanol was added dropwise over 15 min while the temperature of the polymerization reaction liquid was maintained at 80° C. After completion of the dropwise addition, an end treatment was carried out by heating at 80° C. for 2 hrs, and then the polymerization reaction liquid was water-cooled to 30° C. or below.

The cooled polymerization reaction liquid was charged into 500 parts by mass of hexane with respect to 100 parts by mass of the polymerization reaction liquid, and thus precipitated white powder was filtered off. The white powder obtained by filtration was washed twice with 100 parts by mass of hexane with respect to 100 parts by mass of the polymerization reaction liquid, followed by filtering off, and dissolved in 300 parts by mass of 1-methoxy-2-propanol. Next, 500 parts by mass of methanol, 50 parts by mass of triethylamine and 10 parts by mass of ultra pure water were added to the solution, and a hydrolysis reaction was performed with stirring at 70° C. for 6 hrs.

After completion of the reaction, a remaining solvent was distilled away, and the solid thus obtained was dissolved in 100 parts by mass of acetone. The solution was added dropwise into 500 parts by mass of water to allow coagulation of the polymer, and the solid thus obtained was filtered off. Moreover, 3,000 parts by mass of butyl acetate were added to the solid to permit dissolution, and the solid was washed with 3,000 parts by mass of a 5% so by mass aqueous sodium bicarbonate solution. Subsequently, the organic layer was washed three times with 3,000 parts by mass of ultra pure water, and the concentrated until the amount was reduced to 300 parts by mass with respect to total monomers. Thus resulting concentrate was added dropwise into five-times mass of hexane to allow coagulation of the polymer, which was dried at 50° C. for 12 hrs to give a white powdery polymer component (A-1).

### Examples 2 to 6

### Syntheses of Polymer Components (A-2) to (A-6)

Polymer components (A-2) to (A-6) were synthesized in a similar manner to Example 1 except that each monomer of the type and the proportion shown in Table 1 below was used. In Table 1, “-” indicates that the corresponding monomer was not used.

### Example 7

### Synthesis of Polymer Component (A-7)

The monomer (M-1), the monomer (M-4) and the monomer (M-9) were dissolved in 200 parts by mass of 1-methoxy-2-propanol such that the proportion of each structural unit contained in a polymer finally obtained (molar ratio) of 35/45/20 was attained. Next, as a polymerization initiator, 5 mol % AIBN with respect to total monomers was added to prepare a monomer solution. Meanwhile, after a vacant reaction vessel was purged with nitrogen for 30 min, 100 parts by mass of 1-methoxy-2-propanol were added thereto, and heated with stirring to elevate the temperature to 80° C. Subsequently, the monomer solution prepared as described above was added dropwise over 3 hrs, and thereafter the mixture was further heated at 80° C. for 3 hrs, whereby a polymerization reaction was performed for 6 hrs in total. polymerization After completion of the reaction, polymerization reaction liquid was water-cooled to 30° C. or below.

The cooled polymerization reaction liquid was charged into 500 parts by mass of hexane with respect to 100 parts by mass of the polymerization reaction liquid, and thus precipitated white powder was filtered off. The white powder obtained by filtration was so washed twice with 100 parts by mass of hexane with respect to 100 parts by mass of the polymerization reaction liquid, followed by filtering off, and dissolved in 300 parts by mass of 1-methoxy-2-propanol. Next, 500 parts by mass of methanol, 50 parts by mass of triethylamine and 10 parts by mass of ultra pure water were added to the solution, and a hydrolysis reaction was performed with stirring at 70° C. for 6 hrs.

After completion of the reaction, a remaining solvent was distilled away, and the solid thus obtained was dissolved in 100 parts by mass of acetone. The solution was added dropwise into 500 parts by mass of water to allow coagulation of the polymer, and the solid thus obtained was filtered off. Moreover, 3,000 parts by mass of butyl acetate were added to the solid to permit dissolution, and the solid was washed with 3,000 parts by mass of a 5% by mass aqueous sodium bicarbonate solution. Subsequently, the organic layer was washed three times with 3,000 parts by mass of ultra pure water, and the concentrated until the amount was reduced to 300 parts by mass with respect to total monomers. Thus resulting concentrate was added dropwise into five-times mass of hexane to allow coagulation of the polymer, which was dried at 50° C. for 12 hrs to give a white powdery polymer component (A-7).

### Examples 8 to 10

### Syntheses of Polymer Components (A-8) to (A-10)

Polymer components (A-8) to (A-10) were synthesized in a similar manner to Example 7 except that each monomer of the type and the proportion shown in Table 1 below was used.

### Example 11

### Purification of Polymer Component (A-1) by Preparative GPC

The polymer component (A-1) was purified by using preparative GPC available from GL Sciences, Inc., to remove: a fraction corresponding to a cumulative area accounting for 25% of a total area on the GPC elution curve from a shorter retention time; and a fraction corresponding to a cumulative area accounting for 25% of a total area on the GPC elution curve from a longer retention time, whereby a remainder fraction (a fraction corresponding to a cumulative area accounting for 25% to 75% of the total area on the GPC elution area) was preparatively collected to give a polymer component (A-1P). It is to be noted that the total area of the GPC elution curve was assumed to be 100%.

### Reference Synthesis Examples 1 to 2

### Syntheses of Polymer Components (A-11) to (A-12)

Polymer components (A-11) to (A-12) were synthesized in a similar manner to Example 7 except that each monomer of the type and the proportion shown in Table 1 below was used.

### Examples 12 to 14

### Syntheses of Polymer Components (A-13) to (A-15)

Polymer components (A-13) to (A-15) were synthesized in a similar manner to Example 7 except that each monomer of the type and the proportion shown in Table 1 below was used.

### Comparative Synthesis Example 1

### Synthesis of Polymer Component (a-1)

The monomer (M-1), the monomer (M-4) and the monomer (M-9) were dissolved in 60 parts by mass of 1-methoxy-2-propanol such that the proportion of each structural unit contained in a polymer finally obtained (molar ratio) of 35/45/20 was attained. Next, as a chain transfer agent, 3.5 mol % 2-cyano-2-propyl dodecyl trithiocarbonate with respect to total monomers, and as a polymerization initiator, 0.7 mol % AIBN with respect to total monomers were added to prepare a monomer solution. After being purged with nitrogen for 30 min, the monomer solution was heated with stirring to elevate the temperature to 80° C. A time point at which the temperature of the monomer solution was elevated to 80° C. was regarded as the time point of the start of the polymerization reaction, and the polymerization reaction was performed for 6 hrs. After completion of the polymerization reaction, a solution prepared by dissolving 14.3 mol % AIBN with respect to total monomers, and 17.8 mol % tert-dodecanethiol with respect to total monomers in 60 parts by mass of 1-methoxy-2-propanol was added dropwise over 15 min while the temperature of the polymerization reaction liquid was maintained at 80° C. After completion of the dropwise addition, an end treatment was carried out by heating at 80° C. for 2 hrs, and then the polymerization reaction liquid was water-cooled to 30° C. or below.

The cooled polymerization reaction liquid was charged into 500 parts by mass of hexane with respect to 100 parts by mass of the polymerization reaction liquid, and thus precipitated white powder was filtered off. The white powder obtained by filtration was washed twice with 100 parts by mass of hexane with respect to 100 parts by mass of the polymerization reaction liquid, followed by filtering off, and dissolved in 300 parts by mass of 1-methoxy-2-propanol. Next, 500 parts by mass of methanol, 50 parts by mass of triethylamine and 10 parts by mass of ultra pure water were added to the solution, and a hydrolysis reaction was performed with stirring at 70° C. for 6 hrs.

After completion of the reaction, remaining solvent was distilled away, and the solid thus obtained was dissolved in 100 parts by mass of acetone. The solution was added dropwise into 500 parts by mass of water to allow coagulation of the polymer, and the solid thus obtained was filtered off. Drying at 50° C. for 12 hrs gave a white powdery polymer component (a-1).

### Comparative Synthesis Examples 2 to 4

### Syntheses of Polymer Components (a-2) to (a-4)

Polymer components (a-2) to (a-4) were synthesized in a similar manner to Comparative Synthesis Example 1 except that each monomer of the type and the proportion shown in Table 1 below was used.

### Comparative Synthesis Example 5

### Synthesis of Polymer Component (a-5)

The monomer (M-1), the monomer (M-4) and the monomer (M-11) were dissolved in 200 parts by mass of 1-methoxy-2-propanol such that the proportion of each structural unit contained in a polymer finally obtained (molar ratio) of 50/30/20 was attained. Next, as a polymerization initiator, 5 mol % AIBN with respect to total monomers was added to prepare a monomer solution. Meanwhile, after a vacant reaction vessel was purged with nitrogen for 30 min, 100 parts by mass of 1-methoxy-2-propanol were added thereto, and heated with stirring to elevate the temperature to 80° C. Subsequently, the monomer solution prepared as described above was added dropwise over 3 hrs, and thereafter the mixture was further heated at 80° C. for 3 hrs, whereby a polymerization reaction was performed for 6 hrs in total. polymerization After completion of the reaction, polymerization reaction liquid was water-cooled to 30° C. or below.

The cooled polymerization reaction liquid was charged into 500 parts by mass of hexane with respect to 100 parts by mass of the polymerization reaction liquid, and thus precipitated white powder was filtered off. The white powder obtained by filtration was washed twice with 100 parts by mass of hexane with respect to 100 parts by mass of the polymerization reaction liquid, followed by filtering off, and dissolved in 300 parts by mass of 1-methoxy-2-propanol. Next, 500 parts by mass of methanol, 50 parts by mass of triethylamine and 10 parts by mass of ultra pure water were added to the solution, and a hydrolysis reaction was performed with stirring at 70° C. for 6 hrs.

After completion of the reaction, remaining solvent was distilled away, and the solid thus obtained was dissolved in 100 parts by mass of acetone. The solution was added dropwise into 500 parts by mass of water to allow coagulation of the polymer, and the solid thus obtained was filtered off, which was dried at 50° C. for 12 hrs to give a white powdery polymer component (a-5).

Comparative Synthesis Examples 6 to 8: Syntheses of Polymer Components (a-6) to so (a-8)

Polymer components (a-6) to (a-8) were synthesized in a similar manner to Comparative Synthesis Example 5 except that each monomer of the type and the proportion shown in Table 1 below was used.

TABLE 1

| | | Monomer | | Monomer | | Monomer | | | | | | | |
|---|---|---|---|---|---|---|---|---|---|---|---|---|---|
| | | that gives | | that gives | | that gives | | | | | | | |
| | | structural | | structural | | other | | | | | | | |
| | | unit (I) | | unit (II) | | structural unit | | | | | | | |
| | (A) Polymer | | proportion | | proportion | | proportion | Yield | | | X1 | X2 | |
| | component | type | (mol %) | type | (mol %) | type | (mol %) | (%) | Mw | Mw/Mn | (mol %) | (mol %) | X2/X1 |
| Example 1 | A-1 | M-1 | 35 | M-4 | 45 | M-9 | 20 | 77 | 5,600 | 1.29 | 35.1 | 37.2 | 1.06 |
| Example 2 | A-2 | M-1 | 40 | M-4 | 10 | M-10 | 50 | 78 | 5,800 | 1.27 | 39.2 | 44.7 | 1.14 |
| Example 3 | A-3 | M-1 | 30 | M-5 | 20 | M-11 | 20 | 73 | 6,100 | 1.27 | 28.8 | 30.5 | 1.06 |
| | | | | M-7 | 30 | | | | | | | | |
| Example 4 | A-4 | M-2 | 35 | M-6 | 15 | M-12 | 50 | 76 | 5,900 | 1.28 | 35.0 | 37.2 | 1.06 |
| Example 5 | A-5 | M-1 | 55 | M-7 | 45 | — | — | 78 | 5,700 | 1.28 | 55.2 | 57.4 | 1.04 |
| Example 6 | A-6 | M-1 | 40 | M-5 | 30 | M-11 | 10 | 80 | 5,800 | 1.20 | 38.6 | 43.8 | 1.13 |
| | | | | M-7 | 20 | | | | | | | | |
| Example 7 | A-7 | M-1 | 35 | M-4 | 45 | M-9 | 20 | 80 | 6,000 | 1.55 | 45.5 | 46.1 | 1.01 |
| Example 8 | A-8 | M-3 | 45 | M-8 | 55 | — | — | 80 | 6,900 | 1.54 | 36.8 | 38.9 | 1.06 |
| Example 9 | A-9 | M-2 | 25 | M-4 | 15 | M-10 | 20 | 79 | 6,800 | 1.56 | 26.5 | 28.8 | 1.09 |
| | | | | M-5 | 40 | | | | | | | | |
| Example 10 | A-10 | M-3 | 40 | M-7 | 60 | — | — | 79 | 6,900 | 1.55 | 42.7 | 46.9 | 1.10 |
| Example 11 | A-1P | M-1 | 35 | M-4 | 45 | M-9 | 20 | 35 | 5,600 | 1.19 | 37.0 | 37.2 | 1.01 |
| Reference | A-11 | M-1 | 100 | — | — | — | — | 80 | 5,000 | 1.51 | 100.0 | 100.0 | 1.00 |
| Synthesis | | | | | | | | | | | | | |
| Example 1 | | | | | | | | | | | | | |
| Reference | A-12 | — | — | M-7 | 100 | — | — | 80 | 5,500 | 1.52 | — | — | — |
| Synthesis | | | | | | | | | | | | | |
| Example 2 | | | | | | | | | | | | | |
| Example 12 | A-13 | M-1 | 20 | M-5 | 60 | — | — | 80 | 5,300 | 1.55 | 38.7 | 42.1 | 1.09 |
| | | M-13 | 20 | | | | | | | | | | |
| Example 13 | A-14 | M-1 | 20 | M-5 | 60 | — | — | 75 | 5,100 | 1.53 | 38.2 | 41.6 | 1.09 |
| | | M-14 | 20 | | | | | | | | | | |
| Example 14 | A-15 | M-1 | 20 | M-5 | 60 | — | — | 70 | 5,500 | 1.50 | 36.3 | 40.1 | 1.10 |
| | | M-15 | 20 | | | | | | | | | | |
| Comparative | a-1 | M-1 | 35 | M-4 | 45 | M-9 | 20 | 85 | 5,600 | 1.29 | 39.1 | 37.2 | 0.95 |
| Synthesis | | | | | | | | | | | | | |
| Example 1 | | | | | | | | | | | | | |
| Comparative | a-2 | M-1 | 30 | M-5 | 20 | — | — | 73 | 5,800 | 1.27 | 32.1 | 30.1 | 0.94 |
| Synthesis | | | | M-6 | 20 | | | | | | | | |
| Example 2 | | | | M-7 | 30 | | | | | | | | |
| Comparative | a-3 | M-2 | 35 | M-7 | 15 | M-9 | 50 | 76 | 5,900 | 1.28 | 37.9 | 35.4 | 0.93 |
| Synthesis | | | | | | | | | | | | | |
| Example 3 | | | | | | | | | | | | | |
| Comparative | a-4 | M-3 | 40 | M-4 | 60 | — | — | 78 | 6,000 | 1.28 | 55.3 | 44.2 | 0.80 |
| Synthesis | | | | | | | | | | | | | |
| Example 4 | | | | | | | | | | | | | |
| Comparative | a-5 | M-1 | 50 | M-4 | 30 | M-11 | 20 | 80 | 6,700 | 1.55 | 53.2 | 49.2 | 0.92 |
| Synthesis | | | | | | | | | | | | | |
| Example 5 | | | | | | | | | | | | | |
| Comparative | a-6 | M-1 | 40 | M-4 | 30 | M-11 | 30 | 78 | 7,000 | 1.55 | 43.7 | 40.9 | 0.94 |
| Synthesis | | | | | | | | | | | | | |
| Example 6 | | | | | | | | | | | | | |
| Comparative | a-7 | M-2 | 25 | M-8 | 15 | M-10 | 40 | 79 | 6,800 | 1.56 | 26.7 | 24.3 | 0.91 |
| Synthesis | | | | | | M-12 | 20 | | | | | | |
| Example 7 | | | | | | | | | | | | | |
| Comparative | a-8 | M-3 | 60 | M-4 | 40 | — | — | 79 | 6,900 | 1.55 | 63.2 | 61.2 | 0.97 |
| Synthesis | | | | | | | | | | | | | |
| Example 8 | | | | | | | | | | | | | |

### Preparation of Radiation-Sensitive Resin Composition

The acid generating agent (B), the acid diffusion control agent (C) and the solvent (D) used for preparing the radiation-sensitive resin compositions are shown below.

(B) Acid Generating Agent

B-1 to B-6: compounds represented by the following formulae (B-1) to (B-6)

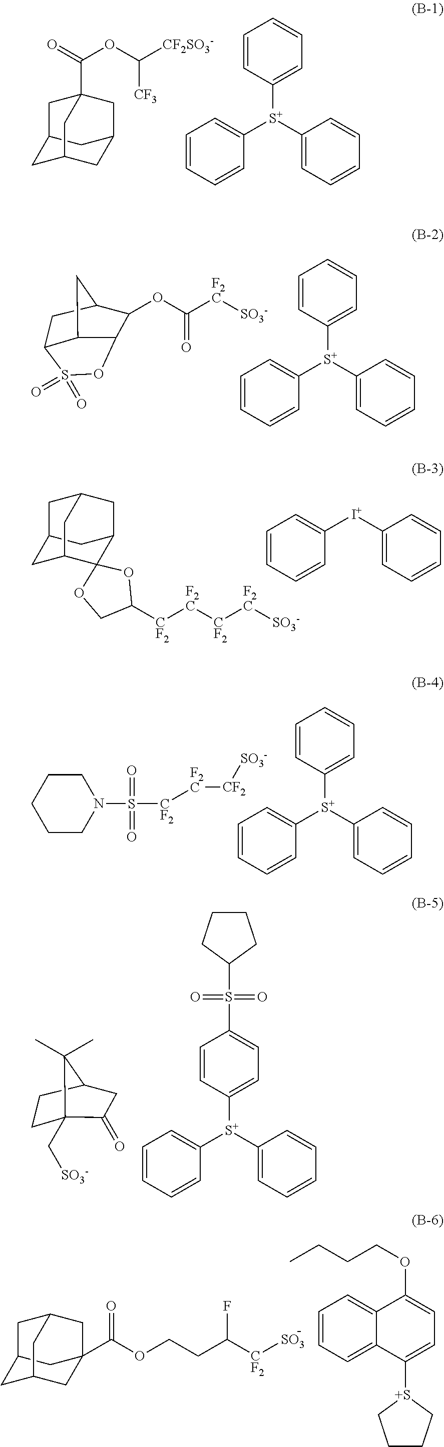

(C) Acid Diffusion Control Agent

C-1 to C-4: compounds represented by the following formulae (C-1) to (C-4)

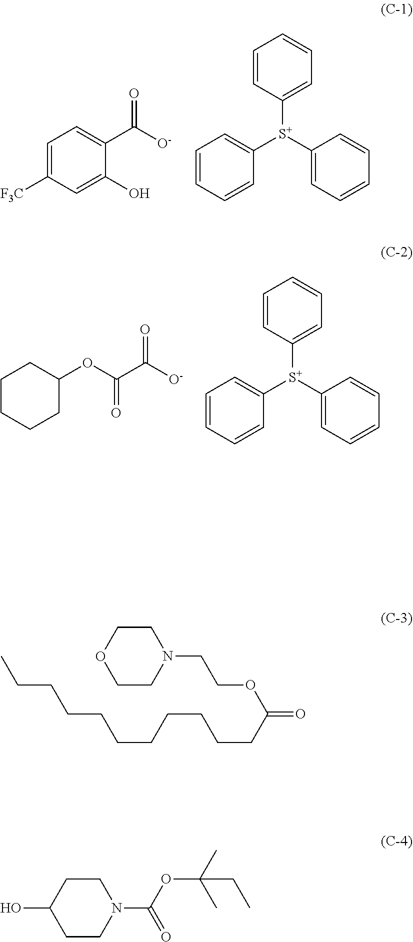 [SMILES: O=C([O-])c1ccc(C(F)(F)F)cc1O ; c1ccc([S+](c2ccccc2)c2ccccc2)cc1 ; O=C([O-])C(=O)OC1CCCCC1 ; c1ccc([S+](c2ccccc2)c2ccccc2)cc1 ; CCCCCCCCCCCC(=O)OCCN1CCOCC1 ; CCC(C)(C)OC(=O)N1CCC(O)CC1]

(D) Solvent

D-1: propylene glycol monomethyl ether acetate

D-2: cyclohexanone

### Example 15

A radiation-sensitive resin composition (R-1) was prepared by: mixing 100 parts by mass of (A-1) as the polymer component (A), 20 parts by mass of (B-1) as the acid generating agent (B), 30 mol % (C-1), with respect to (B-1), as the acid diffusion control agent (C), 4,800 parts by mass of (D-1) and 2,000 parts by mass of (D-2) as the solvent (D); and then filtering a thus obtained mixture through a membrane filter having a pore size of 0.2 μM

### Examples 16 to 36 and Comparative Examples 1 to 10

Radiation-sensitive resin compositions (R-2) to (R-22) and (CR-1) to (CR-10) were prepared by a similar operation to that of Example 15 except that each component of the type and the content shown in Table 2 below was used. It is to be noted that in preparing the radiation-sensitive resin composition (R-19), measurements of X1 and X2 conducted on the mixture obtained by mixing 50 parts by mass of (A-11) and 50 parts by mass of (A-12) revealed inequalities of X1<X2, and X2/X1>1.0. In Example 33, parts by mass of this mixture were used as the polymer component (A).

TABLE 2

| | | | | | | (C) Acid diffusion control | | | |
|---|---|---|---|---|---|---|---|---|---|
| | | (A) Polymer | | (B) Acid generating | | agent | | | |
| | Radiation- | component | | agent | | | content (mol % | (D) Solvent | |
| | sensitive | | content (parts | | content (parts | | with respect to (B) | | content (parts by |
| | composition | Type | by mass) | type | by mass) | type | component) | type | mass) |
| Example 15 | R-1 | A-1 | 100 | B-1 | 20 | C-1 | 30 | D-1/D-2 | 4,800/2,000 |
| Example 16 | R-2 | A-1 | 100 | B-3 | 20 | C-3 | 30 | D-1/D-2 | 4,800/2,000 |
| Example 17 | R-3 | A-1 | 100 | B-2 | 20 | C-1 | 30 | D-1/D-2 | 4,800/2,000 |
| Example 18 | R-4 | A-2 | 100 | B-4 | 20 | C-2 | 30 | D-1/D-2 | 4,800/2,000 |
| Example 19 | R-5 | A-2 | 100 | B-5 | 20 | C-1 | 30 | D-1/D-2 | 4,800/2,000 |
| Example 20 | R-6 | A-3 | 100 | B-3 | 20 | C-1 | 30 | D-1/D-2 | 4,800/2,000 |
| Example 21 | R-7 | A-3 | 100 | B-6 | 20 | C-4 | 30 | D-1/D-2 | 4,800/2,000 |
| Example 22 | R-8 | A-4 | 100 | B-1 | 20 | C-1 | 30 | D-1/D-2 | 4,800/2,000 |
| Example 23 | R-9 | A-4 | 100 | B-2 | 20 | C-4 | 30 | D-1/D-2 | 4,800/2,000 |
| Example 24 | R-10 | A-5 | 100 | B-1 | 20 | C-1 | 30 | D-1/D-2 | 4,800/2,000 |
| Example 25 | R-11 | A-6 | 100 | B-4 | 20 | C-2 | 30 | D-1/D-2 | 4,800/2,000 |
| Example 26 | R-12 | A-7 | 100 | B-2 | 20 | C-3 | 30 | D-1/D-2 | 4,800/2,000 |
| Example 27 | R-13 | A-8 | 100 | B-3 | 20 | C-1 | 30 | D-1/D-2 | 4,800/2,000 |
| Example 28 | R-14 | A-8 | 100 | B-4 | 20 | C-1 | 30 | D-1/D-2 | 4,800/2,000 |
| Example 29 | R-15 | A-9 | 100 | B-5 | 20 | C-2 | 30 | D-1/D-2 | 4,800/2,000 |
| Example 30 | R-16 | A-10 | 100 | B-1 | 20 | C-3 | 30 | D-1/D-2 | 4,800/2,000 |
| Example 31 | R-17 | A-1P | 100 | B-1 | 20 | C-1 | 30 | D-1/D-2 | 4,800/2,000 |
| Example 32 | R-18 | A-1P | 100 | B-2 | 20 | C-3 | 30 | D-1/D-2 | 4,800/2,000 |
| Example 33 | R-19 | A-11 | 50 | B-1 | 20 | C-1 | 30 | D-1/D-2 | 4,800/2,000 |
| | | A-12 | 50 | | | | | | |
| Example 34 | R-20 | A-13 | 100 | B-1 | 20 | C-1 | 30 | D-1/D-2 | 4,800/2,000 |
| Example 35 | R-21 | A-14 | 100 | B-1 | 20 | C-1 | 30 | D-1/D-2 | 4,800/2,000 |
| Example 36 | R-22 | A-15 | 100 | B-1 | 20 | C-1 | 30 | D-1/D-2 | 4,800/2,000 |
| Comparative | CR-1 | a-1 | 100 | B-1 | 20 | C-1 | 30 | D-1/D-2 | 4,800/2,000 |
| Example 1 | | | | | | | | | |
| Comparative | CR-2 | a-1 | 100 | B-2 | 20 | C-3 | 30 | D-1/D-2 | 4,800/2,000 |
| Example 2 | | | | | | | | | |
| Comparative | CR-3 | a-2 | 100 | B-4 | 20 | C-2 | 30 | D-1/D-2 | 4,800/2,000 |
| Example 3 | | | | | | | | | |
| Comparative | CR-4 | a-3 | 100 | B-2 | 20 | C-3 | 30 | D-1/D-2 | 4,800/2,000 |
| Example 4 | | | | | | | | | |
| Comparative | CR-5 | a-4 | 100 | B-3 | 20 | C-1 | 30 | D-1/D-2 | 4,800/2,000 |
| Example 5 | | | | | | | | | |
| Comparative | CR-6 | a-5 | 100 | B-4 | 20 | C-2 | 30 | D-1/D-2 | 4,800/2,000 |
| Example 6 | | | | | | | | | |
| Comparative | CR-7 | a-6 | 100 | B-5 | 20 | C-1 | 30 | D-1/D-2 | 4,800/2,000 |
| Example 7 | | | | | | | | | |
| Comparative | CR-8 | a-7 | 100 | B-3 | 20 | C-1 | 30 | D-1/D-2 | 4,800/2,000 |
| Example 8 | | | | | | | | | |
| Comparative | CR-9 | a-8 | 100 | B-6 | 20 | C-4 | 30 | D-1/D-2 | 4,800/2,000 |
| Example 9 | | | | | | | | | |
| Comparative | CR-10 | a-8 | 100 | B-1 | 20 | C-1 | 30 | D-1/D-2 | 4,800/2,000 |
| Example 10 | | | | | | | | | |

### Resist Pattern Formation

By using a spin coater (Tokyo Electron Limited, “CLEAN TRACK ACTS”), the radiation-sensitive resin composition prepared as described above was applied on the surface of an 12-inch silicon wafer coated with AL412 (Brewer Science, Inc.) having a film thickness of 20 nm, and subjected to PB at 130° C. for 60 sec, followed by cooling at 23° C. for 30 sec to give a resist film having a film thickness of 55 nm. Next, this resist film was irradiated with EUV light using an EUV scanner (model “NXE3300”, manufactured by ASML, NA=0.33, irradiation conditions: Conventional s=0.89, mask imec DEFECT 32 FFR02). Subsequently, PEB was carried out at 110° C. for 60 sec, followed by cooling at 23° C. for 30 sec, and a development with a 2.38% by mass aqueous TMAH solution at 23° C. for 30 sec to form a positive-tone 32-nm line-and-space pattern

### Evaluations

The inhibitory ability of defects, and the sensitivity and the LWR performance of the radiation-sensitive resin compositions were evaluated according to the following methods. For line-width measurement in the evaluations of the sensitivity and the LWR performance of the resist pattern, High-Resolution FEB line-width measurement apparatus (“CG5000”, Hitachi High-Technologies Corporation) was used.

Inhibitory Ability of Defects

On the line-and-space pattern formed as described above, the number of defects (number/cm²) was measured using a defect inspection system (“KLA2925”, KLA-Tencor Corporation). The inhibitory ability of defects was evaluated to be: “favorable” in a case of being no greater than 20/cm²; and “unfavorable” in a case of being greater than 20/cm².

Sensitivity

In the resist pattern formation, an exposure dose at which the 32-nm line-and-space pattern was formed was regarded as optimum exposure dose, and this optimum exposure dose was defined as “sensitivity (mJ/cm²)”.

LWR Performance

The 32-nm line-and-space pattern formed as described above was observed from above the pattern, and the line width was measured at arbitrary 50 points. Then a 3 Sigma value was determined from the distribution of the measurements, and the 3 Sigma value was defined as “LWR performance (nm)”. The smaller value reveals less variance of the line width, indicating a better LWR performance. The LWR performance was evaluated to be: “favorable” in a case of being no greater than 3.1 nm; and “unfavorable” in a case of being greater than 3.1 nm.

TABLE 3

| | | Inhibitory | | |
|---|---|---|---|---|
| | Radiation- | ability of | | LWR |
| | sensitive | defects | Sensitivity | performance |
| | composition | (number/cm²) | (mJ/cm²) | (nm) |
| Example 15 | R-1 | 9 | 42 | 2.8 |
| Example 16 | R-2 | 8 | 35 | 2.7 |
| Example 17 | R-3 | 5 | 42 | 2.8 |
| Example 18 | R-4 | 6 | 48 | 2.6 |
| Example 19 | R-5 | 2 | 46 | 2.7 |
| Example 20 | R-6 | 4 | 37 | 2.9 |
| Example 21 | R-7 | 5 | 49 | 3.0 |
| Example 22 | R-8 | 6 | 46 | 2.7 |
| Example 23 | R-9 | 3 | 31 | 2.9 |
| Example 24 | R-10 | 13 | 38 | 3.1 |
| Example 25 | R-11 | 5 | 48 | 2.7 |
| Example 26 | R-12 | 6 | 46 | 2.6 |
| Example 27 | R-13 | 3 | 49 | 2.5 |
| Example 28 | R-14 | 5 | 41 | 2.3 |
| Example 29 | R-15 | 7 | 43 | 2.5 |
| Example 30 | R-16 | 11 | 38 | 3.0 |
| Example 31 | R-17 | 9 | 44 | 2.9 |
| Example 32 | R-18 | 9 | 36 | 2.7 |
| Example 33 | R-19 | 20 | 42 | 3.5 |
| Example 34 | R-20 | 5 | 40 | 3.3 |
| Example 35 | R-21 | 11 | 45 | 3.0 |
| Example 36 | R-22 | 9 | 50 | 2.5 |
| Comparative | CR-1 | 75 | 42 | 3.5 |
| Example 1 | | | | |
| Comparative | CR-2 | 102 | 35 | 3.2 |
| Example 2 | | | | |
| Comparative | CR-3 | 89 | 46 | 3.2 |
| Example 3 | | | | |
| Comparative | CR-4 | 110 | 42 | 3.5 |
| Example 4 | | | | |
| Comparative | CR-5 | 164 | 37 | 3.6 |
| Example 5 | | | | |
| Comparative | CR-6 | 98 | 46 | 3.4 |
| Example 6 | | | | |
| Comparative | CR-7 | 132 | 45 | 3.6 |
| Example 7 | | | | |
| Comparative | CR-8 | 126 | 46 | 3.8 |
| Example 8 | | | | |
| Comparative | CR-9 | 92 | 42 | 3.9 |
| Example 9 | | | | |
| Comparative | CR-10 | 194 | 40 | 3.8 |
| Example 10 | | | | |

As is clear from the results shown in Table 3, the radiation-sensitive resin compositions of Examples were all superior in the inhibitory ability of defects, and the LWR performance. Also, the radiation-sensitive resin composition prepared by using the polymer component (A-1P) obtained through purification on preparative GPC exhibited equivalent inhibitory ability of defects, and the LWR performance.

### INDUSTRIAL APPLICABILITY

The radiation-sensitive resin composition and the resist pattern-forming method of o the embodiments of the present invention enable a resist pattern with less LWR and fewer defects to be formed, while the sensitivity is maintained. The polymer component of the embodiment of the present invention can be suitably used as a component of the radiation-sensitive resin composition of the embodiment of the invention. Therefore, these can be suitably used in manufacture of semiconductor devices in which further progress of miniaturization is expected in the future.

What is claimed is:

1. A radiation-sensitive resin composition which comprises:
a polymer component comprising in a single polymer or different polymers, a first structural unit that comprises a phenolic hydroxyl group and a second structural unit that comprises an acid-labile group; and
a radiation-sensitive acid generator,
wherein, the polymer component satisfies inequality (A):
X1<X2 (A)
wherein, in the inequality (A), X1 represents a proportion (mol %) of the first structural unit comprised with respect to total structural units constituting the polymer component comprised in a fraction eluted until a retention time at which a cumulative area accounts for 1% of a total area on a gel permeation chromatography (GPC) elution curve of the polymer component detected by a differential refractometer; and X2 represents a proportion (mol %) of the first structural unit comprised with respect to total structural units constituting the polymer component.

2. A radiation-sensitive resin composition which comprises:
a polymer component comprising in a single polymer or different polymers, a first structural unit that comprises a phenolic hydroxyl group and a second structural unit that comprises an acid-labile group; and
a radiation-sensitive acid generator,
wherein, the polymer component satisfies inequality (B):
$$\frac{X 2}{X 1} > 1.0 \qquad ( B )$$
wherein, in the inequality (B), X1 represents a proportion (mol %) of the first structural unit comprised with respect to total structural units constituting the polymer component comprised in a fraction eluted until a retention time at which a cumulative area accounts for 1% of a total area on a gel permeation chromatography (GPC) elution curve of the polymer component detected by a differential refractometer; and X2 represents a proportion (mol %) of the first structural unit comprised with respect to total structural units constituting the polymer component.

3. The radiation-sensitive resin composition according to claim 1, wherein the first structural unit is represented by formula (1): 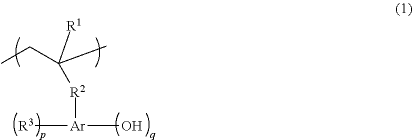
wherein, in the formula (1), R¹ represents a hydrogen atom, a fluorine atom, a methyl group or a trifluoromethyl group; R²represents a single bond, —O—, —COO—* or —CONH—*, wherein * denotes a binding site to Ar; Ar represents a group obtained from an arene having 6 to 20 ring atoms by removing (p+q+1) hydrogen atoms on the aromatic ring; p is an integer of 0 to 10, wherein in a case in which p is 1, R³ represents a monovalent organic group having 1 to 20 carbon atoms or a halogen atom, and in a case in which p is no so less than 2, a plurality of R³s are identical or different, and each represent a monovalent organic group having 1 to 20 carbon atoms or a halogen atom, or at least two of the plurality of R³s taken together represent a part of a ring structure having 4 to 20 ring atoms together with the carbon atom to which the at least two of the plurality of R³s bond; and q is an integer of 1 to 11, wherein (p+q) is no greater than 11.

4. The radiation-sensitive resin composition according to claim 1, wherein the second structural unit is represented by formula (2-1A), formula (2-1B), formula (2-1C), formula (2-2A) or formula (2-2B): 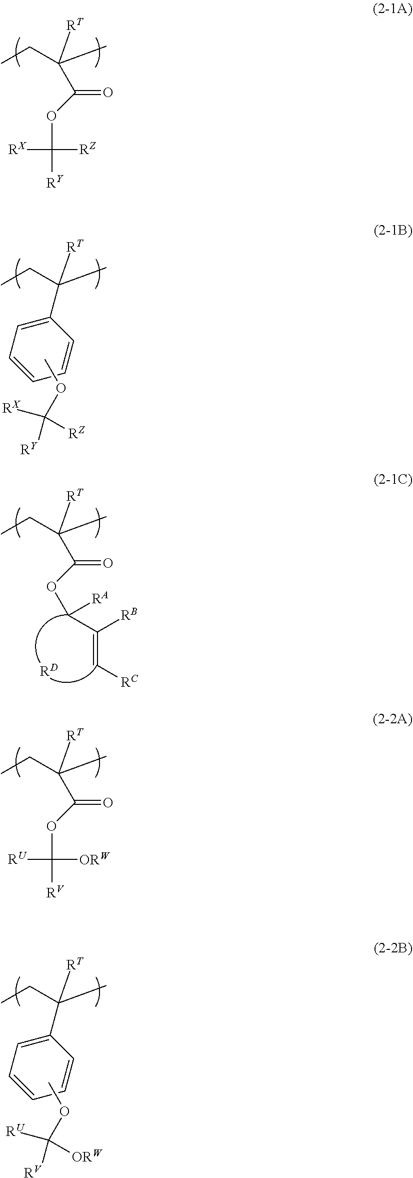
wherein,
in the formulae (2-1A), (2-1B), (2-1C), (2-2A) and (2-2B), R^{T}s each independently represent a hydrogen atom, a fluorine atom, a methyl group or a trifluoromethyl group:
in the formulae (2-1A) and (2-1B), R^{X}s each independently represent a monovalent hydrocarbon group having 1 to 20 carbon atoms; R^{Y} and R^{Z} each independently represent a monovalent hydrocarbon group having 1 to 20 carbon atoms, or R^{Y} and R^{Z} taken together represent a part of an alicyclic structure having 3 to 20 ring atoms together with the carbon atom to which R^{Y} and R^{Z} bond.
in the formula (2-1C), R^{A} represents a hydrogen atom; R^{B} and R^{C} each independently represent a hydrogen atom or a monovalent hydrocarbon group having 1 to 20 carbon atoms; R^{D} represents a divalent hydrocarbon group having 1 to 20 carbon atoms constituting an unsaturated alicyclic structure having 4 to 20 ring atoms together with the carbon atoms to which R^{A}, R^{B} and R^{C} each bond;
in the formulae (2-2A) and (2-2B), R^{U} and R^{V} each independently represent a hydrogen atom or a monovalent hydrocarbon group having 1 to 20 carbon atoms; R^{W}s each independently represent a monovalent hydrocarbon group having 1 to 20 carbon atoms, or R^{U} and R^{V} taken together represent a part of an alicyclic structure having 3 to 20 ring atoms together with the carbon atom to which R^{U} and R^{V} bond, or R^{U} and R^{W} taken together represent a part of an aliphatic heterocyclic structure having 5 to 20 ring atoms together with the carbon atom to which R^{U} bonds and the oxygen atom to which R^{W} bonds.

5. The radiation-sensitive resin composition according to claim 1, wherein the polymer component further comprises other structural unit than the first structural unit or the second structural unit.

6. The radiation-sensitive resin composition according to claim 1, wherein a ratio of a polystyrene-equivalent weight-average molecular weight as determined by gel permeation chromatography to a polystyrene-equivalent number-average molecular weight of the polymer component as determined by gel permeation chromatography is no less than 1.4.

7. A resist pattern-forming method comprising:
applying the radiation-sensitive resin composition according to claim 1 directly or indirectly on a substrate;
exposing a resist film provided by the applying; and
developing the resist film exposed.

8. A polymer composition which comprises a polymer component comprising in a single polymer or different polymers, a first structural unit that comprises a phenolic hydroxyl group and a second structural unit that comprises an acid-labile group,
wherein, the polymer component satisfies inequality (A):
X1<X2 (A)
wherein, in the inequality (A), X1 represents a proportion (mol %) of the first structural unit comprised with respect to total structural units constituting the polymer component comprised in a fraction eluted until a retention time at which a cumulative area accounts for 1% of a total area on a gel permeation chromatography (GPC) elution curve of the polymer component detected by a differential refractometer; and X2 represents a proportion (mol %) of the first structural unit comprised with respect to total structural units constituting the polymer component.

9. A polymer composition which comprises a polymer component comprising in a single polymer or different polymers, a first structural unit that comprises a phenolic hydroxyl group and a second structural unit that comprises an acid-labile group,
the polymer component satisfies inequality (B):
$$\frac{X 2}{X 1} > 1.0 \qquad ( B )$$
wherein, in the inequality (B), X1 represents a proportion (mol %) of the first structural unit comprised with respect to total structural units constituting the polymer component comprised in a fraction eluted until a retention time at which a cumulative area accounts for 1% of a total area on a gel permeation chromatography (GPC) elution curve of the polymer component detected by a differential refractometer; and X2 represents a proportion (mol %) of the first structural unit comprised with respect to total structural units constituting the polymer component.
